(19) United States
(12) Patent Application Publication
(10) Pub. No.: US 2017/0167019 A1
(43) Pub. Date: Jun. 15, 2017

(54) PLASMA PROCESSING APPARATUS AND FILM DEPOSITION METHOD

(71) Applicant: Tokyo Electron Limited, Tokyo (JP)

(72) Inventors: Kazuhide HASEBE, Yamanashi (JP); Shigehiro MIURA, Iwate (JP)

(21) Appl. No.: 15/364,418

(22) Filed: Nov. 30, 2016

(30) Foreign Application Priority Data
Dec. 9, 2015 (JP) 2015-240059

(51) Int. Cl. C23C 16/455; H01J 37/32; C23C 16/52; C23C 16/458; H01L 21/02; C23C 16/505

(52) U.S. Cl. CPC C23C 16/45544; H01L 21/0228; H01L 21/02274; H01L 21/02164; H01L 21/02211; C23C 16/45536; C23C 16/505; C23C 16/52; C23C 16/4584; H01J 37/3211; H01J 37/32752; H01J 37/3244; H01J 2237/332; H01J 2237/20214

(57) ABSTRACT

A plasma processing apparatus includes a process chamber, and a susceptor provided in the process chamber and having a substrate receiving area formed in a top surface thereof. A first plasma generator is configured to perform a first plasma process on a first predetermined area in the substrate receiving area. A first radio frequency power source is connected to the first plasma generator and configured to supply first radio frequency power to the first plasma generator. A second plasma generator is configured to perform a second plasma process on a second predetermined area in the substrate receiving area and to be able to change the second predetermined area. A second radio frequency power source is connected to the second plasma generator and configured to supply second radio frequency power to the second plasma generator.

### CROSS-REFERENCE TO RELATED APPLICATIONS

This patent application is based upon and claims the benefit of priority of Japanese Patent Application No. 2015-240059, filed on Dec. 9, 2015, the entire contents of which are incorporated herein by reference.

### BACKGROUND OF THE INVENTION

1. Field of the Invention

The present invention relates to a plasma processing apparatus and a film deposition method.

2. Description of the Related Art

ALD (Atomic Layer Deposition) and MLD (Molecular Layer Deposition) in which a plurality kinds of process gases (reaction gases) that react with each other is sequentially supplied to a surface of a wafer, thereby depositing a reaction product on the surface of the wafer, are known as one of methods for depositing a thin film such as a silicon oxide film (SiO₂) on a substrate such as a semiconductor wafer. For example, there is a turntable type film deposition apparatus that is combined with a plasma source as one of the ALD film deposition apparatuses, as described in Japanese Laid-Open Patent Application Publication No. 2013-45903. More specifically, the turntable type film deposition apparatus with the plasma source includes a turntable on which five or six wafers are arranged along the circumferential direction, and an antenna to convert a gas to plasma arranged to face a path of the wafers moving by rotation of the turntable.

For example, high-quality and high-speed ALD film deposition can be implemented by using such an apparatus. For example, in the high-quality SiO₂ film deposition, there is a method including steps of supplying a Si-containing gas such as 3DMAS (tris(dimethylamino)silane) or an organic aminosilane gas to a source gas supply area, supplying an oxidation gas such as O₃ to a reaction gas supply area, supplying a mixed gas of argon, hydrogen and oxygen to a plasma processing area, respectively, and causing a wafer to pass through these areas at a high speed, thereby depositing a high-quality SiO₂ film on the wafer. In such a method, a layer of the Si source adsorbed on the wafer in the source gas supply area is oxidized in the reaction gas supply area, and then modified in the plasma processing area where the plasma density and the modification effect are high. Furthermore, the Si adsorption continuously occurs again in the source gas supply area, which makes it relatively easy to acquire uniformity of film deposition across the wafer.

However, along with miniaturization of circuit patterns, for example, as aspect ratios of trenches in trench isolation structures and spaces in line and space patterns increase, it is sometimes difficult to fill up the trenches and the spaces with a film. For example, when a space having a width of about 30 nm is tried to be filled up with a silicon oxide film, because a reaction gas is unlikely to go into the bottom forming a narrow space, the film thickness around a top end of the space of the film deposited on the side wall of the line that also forms the space is likely to become thick, and the film thickness around the bottom is likely to become thin. Thus, the silicon oxide film filling the space may contain a void. When such a silicon oxide film is etched in the subsequent etching process, an opening in communication with the void may be formed in the top surface of the silicon oxide film. In such a case, an etching gas (or an etching solution) may invade from the opening into the silicon oxide film, which may cause contamination, or metal may enter the void during the subsequent metallization process, which may cause a defect.

Such a problem may occur not only in ALD but also in CVD (Chemical Vapor Deposition). For example, when a conductive contact hole (so-called plug) is formed by filling a contact hole formed in a semiconductor substrate with a film made of a conductive material, a void is sometimes formed in the plug. Therefore, to prevent this, Japanese Laid-Open Patent Application Publication No. 2013-135154 describes a film deposition method in which an organic aminosilane gas is caused to adsorb on a surface in a trench; an adsorption site is formed by adsorption of an OH group; and an upper portion of the trench is oxidized by oxidation plasma, thereby leaving many OH groups on and around the bottom and few OH groups at and around the opening portion. When a silicon oxide film is deposited in such a state, the silicon oxide film is deposited so as to becomes thick on and around the bottom and to become thin with the decreasing distance to the opening portion (upper end) with high bottom-up properties, thereby preventing the generation of the void.

However, the film deposition method as described in Japanese Laid-Open Patent Application Publication No. 2013-135154 in which the distribution of OH groups is controlled by plasma and thereby controlling an amount of adsorption of the organic aminosilane gas is often more difficult to acquire preferable uniformity across the substrate than the film deposition method of causing one layer of a source gas on a substrate, oxidizing the one layer of the source gas, and modifying the one oxidized layer. When a turntable type plasma processing apparatus or plasma processing apparatus is used, in the control of the distribution of OH groups by the plasma source, oxidation is likely to be insufficient at the periphery and many OH groups are likely to be present at the periphery because the peripheral portion rotates and moves faster than the central portion around the axis due to a difference in angular velocity. Thus, the amount of adsorption of the organic aminosilane at the periphery is likely to be more than that of the central portion, and the film thickness at the periphery is sometimes thicker than that of the central portion.

Moreover, in other types of substrate processes and plasma processes that do not control the OH groups, with respect to the turntable type plasma processing apparatus, a supply of plasma at the periphery is likely to be lower than the supply at the central portion due to the above-mentioned difference in angular velocity, and a disproportion of the plasma process between the central portion and the peripheral portion of the turntable is liable to be generated.

Furthermore, when the turntable type plasma processing apparatus is not used, a regional distribution of the plasma process is sometimes desired to be adjusted.

### SUMMARY OF THE INVENTION

Embodiments of the present invention provide a plasma processing apparatus and a film deposition method solving one or more of the problems discussed above.

More specifically, embodiments of the present invention provide a plasma processing apparatus and a film deposition method that have high plasma controllability and can obtain preferable uniformity of film thickness, coverage performance and film quality across a surface of a substrate.

According to one embodiment of the present invention, there is provided a plasma processing apparatus includes a process chamber, and a susceptor provided in the process chamber and having a substrate receiving area formed in a top surface thereof. A first plasma generator is configured to perform a first plasma process on a first predetermined area in the substrate receiving area. A first radio frequency power source is connected to the first plasma generator and configured to supply first radio frequency power to the first plasma generator. A second plasma generator is configured to perform a second plasma process on a second predetermined area in the substrate receiving area and to be able to change the second predetermined area. A second radio frequency power source is connected to the second plasma generator and configured to supply second radio frequency power to the second plasma generator.

According to another embodiment of the present invention, there is provided a film deposition method. In the film deposition method, a source gas is supplied to a surface of a substrate. A reaction gas capable of producing a reaction product by reacting with the source gas is supplied to the surface of the substrate while converting the reaction gas to plasma, thereby depositing the reaction product on the surface of the substrate. A disproportion of a degree of reaction of the source gas on the surface of the substrate with the reaction gas is corrected by supplying the reaction gas while converting the reaction gas to plasma to an area where the degree of reaction of the source gas on the surface of the substrate with the reaction gas is smaller than the other area.

Additional objects and advantages of the embodiments are set forth in part in the description which follows, and in part will become obvious from the description, or may be learned by practice of the invention. The objects and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a schematic vertical cross-sectional view illustrating an example of a plasma processing apparatus according to an embodiment of the present invention;

FIG. 2 is a schematic plan view illustrating an example of the plasma processing apparatus according to an embodiment of the present invention;

FIG. 3 is a cross-sectional view cut along a concentric circle of a turntable in the plasma processing apparatus according to an embodiment of the present invention;

FIG. 4 is a vertical cross-sectional view illustrating an example of a first plasma generator according to an embodiment of the present invention;

FIG. 5 is an exploded perspective view illustrating an example of a first plasma generator according to an embodiment of the present invention;

FIG. 6 is a perspective view illustrating an example of a housing provided in a first plasma generator according to an embodiment of the present invention;

FIG. 7 is a plan view illustrating an example of a first plasma generator according to an embodiment of the present invention;

FIG. 8 is a perspective view illustrating a part of a Faraday shield provided in a first plasma generator according to an embodiment of the present invention;

FIG. 9A is a schematic configuration diagram illustrating an example of a second plasma generator of a plasma processing apparatus according to an embodiment of the present invention;

FIG. 9B is a circuit diagram illustrating an example of a second plasma generator of a plasma processing apparatus according to an embodiment;

FIG. 10 is a vertical cross-sectional view illustrating an example of a second plasma generator of a plasma processing apparatus according to an embodiment;

FIG. 11 is an exploded perspective view illustrating an example of a second plasma generator of a plasma processing apparatus according to an embodiment;

FIG. 12 is a plan view illustrating an example of a second plasma generator of a plasma processing apparatus according to an embodiment;

FIG. 13 is a plan view illustrating an example of a positional relationship between ab¥n antenna and a wafer in a second plasma generator according to an embodiment;

FIG. 14 is a circuit diagram showing a second plasma generator of a plasma processing apparatus of a working example;

FIG. 15 is a diagram showing a result of a working example 1;

FIG. 16 is a diagram showing a result of a working example 2;

FIG. 17 is a diagram showing a result of a working example 3;

FIG. 18 is a diagram showing a result of a working example 4;

FIG. 19 is a graph showing a curve schematically illustrating a correlation between a capacitance value of a variable capacitance mechanism and a radio frequency current value flowing through an auxiliary antenna;

FIG. 20A is a diagram illustrating an example of a plasma processing apparatus according to an embodiment of the present invention;

FIG. 20B is a diagram illustrating a state of a wafer before a process starts;

FIG. 20C is a diagram illustrating an example of a source gas supply process;

FIG. 20D is a diagram illustrating a state of a recessed pattern of a surface of a wafer after a source gas supply process ends by using a chemical formula;

FIG. 20E is a diagram illustrating a state of a recessed pattern of a surface of a wafer after a source gas supply process ends by film;

FIG. 20F is a diagram illustrating an example of an oxidation process and a modification process;

FIG. 20G is a diagram illustrating a state of a surface of a wafer including a recessed pattern after the oxidation process and the modification process end;

FIG. 20H is a diagram illustrating a state of the surface of the wafer including the recessed pattern after the oxidation process and the modification process end;

FIG. 20I is a diagram illustrating an example of a second source gas supply process;

FIG. 20J is a diagram illustrating a state of the surface of the wafer including the recessed pattern after the second source gas supply process ends by using a chemical formula;

FIG. 20K is a diagram illustrating a state of the surface of the wafer including the recessed pattern after the second source gas supply process ends by film;

FIG. 21 is a plan view illustrating an example of a plasma processing apparatus according to an embodiment of the present invention; and

FIG. 22 is a perspective view illustrating a second plasma generator according to an embodiment of the present invention.

### DETAILED DESCRIPTION OF THE PREFERRED EMBODIMENTS

Embodiments of the present invention are described below with reference to accompanying drawings.

### First Embodiment

<Configuration of Plasma Processing Apparatus>

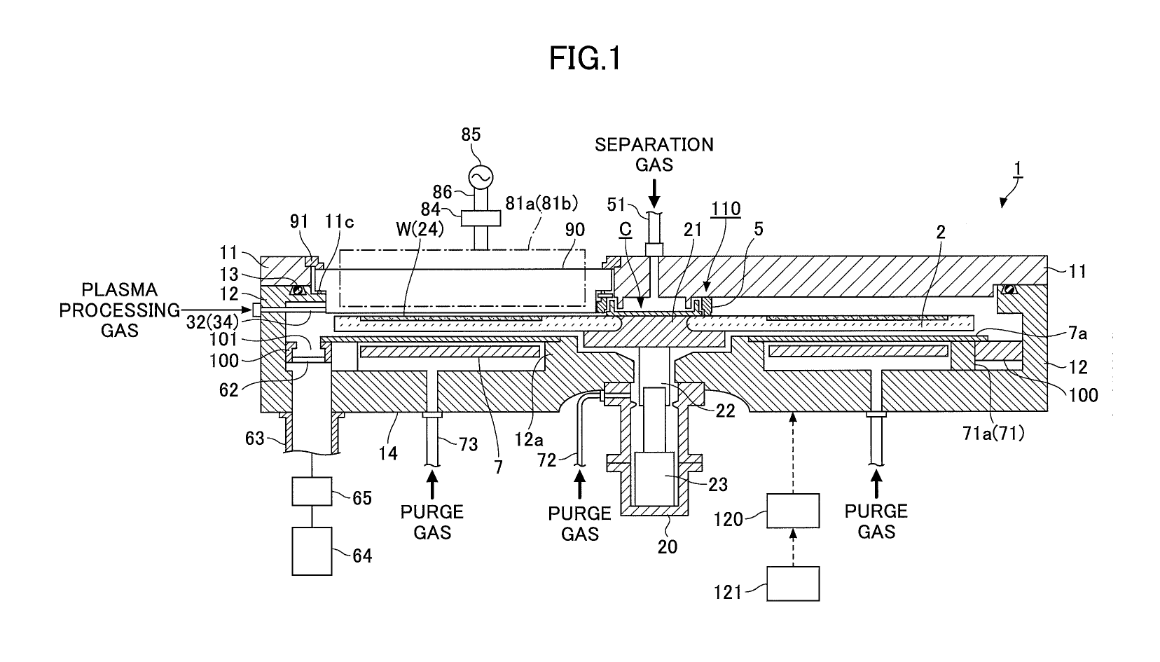

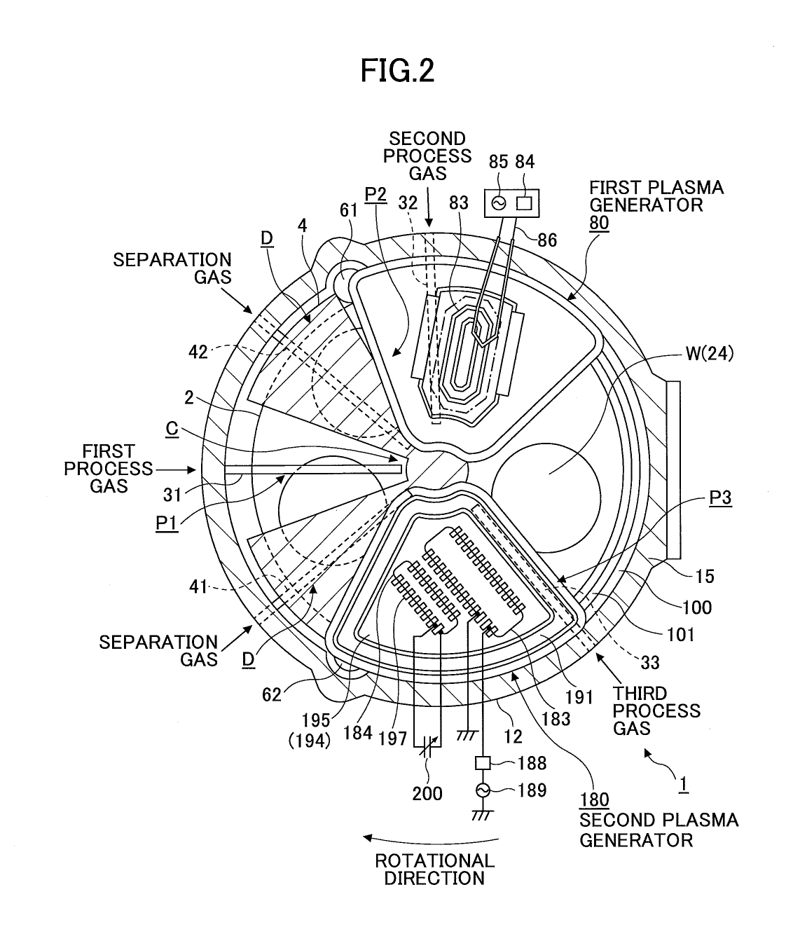

FIG. 1 is a schematic vertical cross-sectional view illustrating an example of a plasma processing apparatus according to a first embodiment. FIG. 2 is a schematic plan view illustrating an example of the plasma processing apparatus according to the first embodiment of the present invention. Here, in FIG. 2, a depiction of a ceiling plate 11 is omitted for the purpose of illustration.

As illustrated in FIG. 1, the plasma processing apparatus according to the first embodiment of the present invention includes a vacuum chamber 1 having an approximately circular planar shape and a turntable 2 provided in the vacuum chamber 1 and having its rotational center in common with the center of the vacuum chamber 1 to rotate a wafer W placed thereon.

The vacuum chamber 1 includes a ceiling plate (ceiling part) 11 provided in a position facing concave portions 24 of the turntable 2 described later, and a chamber body 12. Moreover, a seal member 13 having a ring-like shape is provided in a periphery in an upper surface of the chamber body 12. The ceiling plate 11 is configured to be detachable and attachable from and to the chamber body 12. A diameter dimension (inner diameter dimension) of the vacuum chamber 1 when seen in a plan view is not limited, but can be, for example, set at about 1100 mm.

A separation gas supply pipe 51 is connected to a central part in an upper surface of the ceiling plate 11 and is further in communication with a central part on the upper surface side of a space within the vacuum chamber 1 to supply a separation gas for preventing different process gases from mixing with each other in a central area C.

The turntable 2 is fixed to a core portion 21 having an approximately cylindrical shape at the central part, and is configured to be rotatable by a drive unit 23 in a clockwise fashion as illustrated in FIG. 2 as an example, around a rotational shaft 22 connected to a lower surface of the core portion 21 and extending in a vertical direction, which forms a vertical axis. The diameter dimension of the turntable 2 is not limited, but can be set at, for example, about 1000 mm.

The rotational shaft 22 and the drive unit 23 are accommodated in a casing body 20, and a flange portion on the upper surface side of the casing body 20 is hermetically attached to a lower surface of a bottom portion of the vacuum chamber 1. A purge gas supply pipe 72 for supplying nitrogen gas or the like as a purge gas (separation gas) is connected to an area below the turntable 2.

A peripheral side of the core portion 21 in a bottom part 14 of the vacuum chamber 1 forms a protruding part 12a by being formed into a ring-like shape so as to come to close to the lower surface of the turntable 2.

As shown in FIG. 2, circular concave portions 24 are formed in a surface of the turntable 2 as a substrate receiving area to receive wafers W having a diameter dimension of, for example, 300 mm thereon. The concave portions 24 are provided at a plurality of locations, for example, at five locations along a rotational direction of the turntable 2. Each of the concave portions 24 has an inner diameter slightly larger than the diameter of the wafer W, more specifically, larger than the diameter of the wafer W by about 1 to 4 mm. Furthermore, the depth of each of the concave portions 24 is configured to be approximately equal to or greater than the thickness of the wafer W. Accordingly, when the wafer W is accommodated in the concave portion 24, the surface of the wafer W is as high as, or lower than a surface of the turntable 2 where the wafer W is not placed. Here, even when the depth of each of the concave portions 24 is greater than the thickness of the wafer W, the depth of each of the concave portion 24 is preferred to be equal to or smaller than about three times the thickness of the wafer W because too deep concave portions 24 may affect the film deposition.

Through holes not illustrated in the drawings are formed in a bottom surface of the concave portion 24 to allow, for example, three lifting pins described later to push up the wafer W from below and to lift the wafer W.

As illustrated in FIG. 2, multiple, for example, five nozzles 31, 32, 33, 41 and 42 each made of, for example, quartz are arranged in a radial fashion at intervals in the circumferential direction of the vacuum chamber 1 at respective positions opposite to a passing area of the concave portions 24. Each of the nozzles 31, 32, 33, 41 and 42 is arranged between the turntable 2 and the ceiling plate 11. These nozzles 31, 32, 34, 41 and 42 are each installed, for example, so as to horizontally extend facing the wafer W from an outer peripheral wall of the vacuum chamber 1 toward the central area C.

In the example illustrated in FIG. 2, a first process gas nozzle 31, a separation gas nozzle 42, a second process gas nozzle 32, a third process gas nozzle 33, and a separation gas nozzle 41 are arranged in a clockwise fashion (in the rotational direction of the turntable 2) in this order. However, the plasma processing apparatus according to the present embodiment is not limited to this form, and the turntable 2 may rotate in a counterclockwise fashion. In this case, the first process gas nozzle 31, the separation gas nozzle 42, the second process gas nozzle 32, the third process gas nozzle 33 and the separation gas nozzle 41 are arranged in this order in the counterclockwise fashion.

As illustrated in FIG. 2, plasma generators 80 and 180 are provided above the second process gas nozzle 32 and the third process gas nozzle 33, respectively, to convert plasma processing gases discharged from each of the plasma processing gas nozzles 32 and 33. These plasma generators 80 and 180 are described later.

Here, in the present embodiment, although an example of arranging a single nozzle in each process area is illustrated, a configuration of providing a plurality of nozzles in each process area is also possible. For example, the second process gas nozzle 32 may be constituted of a plurality of plasma processing gas nozzles, each of which is configured to supply argon (Ar) gas, ammonia (NH₃) gas, hydrogen (H₂) gas or the like, or maybe constituted of only a single plasma processing gas nozzle configured to supply a mixed gas of argon gas, ammonia gas and hydrogen gas.

The first process gas nozzle 31 forms a first process gas supply part. Moreover, the second process gas nozzle 32 forms a first plasma processing gas supply part, and the third process gas nozzle 33 forms a second plasma processing gas supply part. Furthermore, each of the separation gas nozzles 41 and 42 forms a separation gas supply part.

Each of the nozzles 31, 32, 33, 41 and 42 is connected to each gas supply source not illustrated in the drawings through a flow control valve.

The first process gas nozzle 31 may supply a variety of process gases depending on the intended purpose, and for example, may supply a source gas containing an element that constitutes a major component of a reaction product forming a film. For example, when a film such as SiO₂, SiN is deposited, a Si-containing gas such as an organic aminosilane gas is supplied. When a TiN film is deposited, a Ti-containing gas such as TiCl₄ is supplied.

A silicon-containing gas may be used as an example of the first process gas supplied from the first process gas nozzle 31 such as DCS [dichlorosilane], HCD [hexachlorodisilane], DIPAS [diisopropylamino-silane], 3DMAS [tris(dimethylamino)silane] gas, BTBAS [bis(tertiary-butyl-amino)silane] or the like. Also, a metal-containing gas maybe used as an example of the first process gas supplied from the first process gas nozzle 31 such as TiCl₄ [titanium tetrachloride], Ti (MPD) (THD)₂ [titanium methylpentanedionato bis(tetramethylheptanedionato)], TMA [trimethylaluminium], TEMAZ [Tetrakis(ethylmethylamino)zirconium], TEMHF [tetrakis (ethylmethylamino)hafnium], Sr(THD)₂ [strontium bis(tetramethylheptanedionato)] or the like.

The plasma processing gases supplied from the second process gas nozzle 32 and the third process gas nozzle 33 can be properly selected depending on intended purpose of the plasma. For example, argon gas or helium (He) gas mainly used for plasma generation, an oxidation gas for oxidizing the first process gas adsorbed on the wafer W and modifying the obtained oxide film (e.g., O₂ gas, O₃ gas or the like), and a nitriding gas for nitrizing the first process gas adsorbed on the wafer W and modifying the obtained nitrized film (e.g., NH₃ gas) are cited as examples. Here, the first and second plasma processing gases discharged from the second and third process gas nozzles 32 and 33 may be the same gas species, or may be different gas species from each other such as O₂ gas and O₃ gas as long as the second plasma processing gas supplied from the third process gas nozzle 33 is intended to modify the reaction product (film) as well as the first plasma processing gas supplied from the second process gas nozzle 32. Each of the plasma processing gases can be selected depending on a desired plasma process.

For example, argon (Ar) gas or the like is cited as an example of the separation gas supplied from the separation gas nozzles 41 and 42.

As discussed above, in the example illustrated in FIG. 2, the first process gas nozzle 31, the separation gas nozzle 42, the second process gas nozzle 32, the third process gas nozzle 33 and the separation gas nozzle 41 are arranged in this order in a clockwise fashion (in the rotational direction of the turntable 2). In other words, in an actual process of the wafer W, the wafer W to which the first process gas is supplied from the first process gas nozzle 31 is sequentially exposed to the separation gas from the separation gas nozzle 42, the plasma processing gas from the second process gas nozzle 32, the plasma processing gas from the third process gas nozzle 33, and the separation gas from the separation gas nozzle 41 in this order.

Gas discharge holes 34 for discharging each of the above-mentioned gases are formed in each lower surface (the surface facing the turntable 2) of the gas nozzles 31, 32, 33, 41 and 42 along a radial direction of the turntable 2 at a plurality of locations, for example, at regular intervals. Each of the nozzles 31, 32, 33, 41 and 42 is arranged so that a distance between a lower end surface of each of the nozzles 31, 32, 33, 41 and 42 and an upper surface of the turntable 2 is set at, for example, about 1 to 5 mm.

An area under the first process gas nozzle 31 is a first process area P1 to allow the first process gas (i.e., source gas) to adsorb on the wafer W. An area under the second process gas nozzle 32 is a second process area P2 to supply a reaction gas that can react with the source gas adsorbed on the surface of the wafer W and produce a reaction product after being converted to plasma, thereby depositing the reaction product on the surface of the wafer W. An area under the third process gas nozzle 33 is a third process area P3 to supply a reaction gas, while converting the reaction gas to plasma, to an area where a degree of reaction of the source gas with the reaction gas on the surface of the wafer is low, in order to enhance the degree of reaction of the source gas with the reaction gas. In other words, in the third process area P3, a process for correcting a disproportion of the degree of reaction of the reaction product produced by passing through the second process area P2, is performed. To do this, while the first plasma generator 80 for the second process area P2 is configured to generate constant plasma, the second plasma generator 180 for the third process area P3 is configured to be able to change a plasma generation area. In other words, while a single antenna 83 is provided in the first plasma generator 80, a main antenna 83 connected to a radio frequency power source 189, and an auxiliary antenna 84 that is not connected to the radio frequency power source 189 and is electrically floating, are provided in the second plasma generator 180. Thus, the second plasma generator 180 is configured to be able to variously adjust currents flowing through the main antenna 83 and the auxiliary antenna 84, and to be able to generate the plasma in any or a desired area. The detailed configuration of the first and second plasma generators 80 and 180 is described later, and the overall configuration of the plasma processing apparatus is described at first.

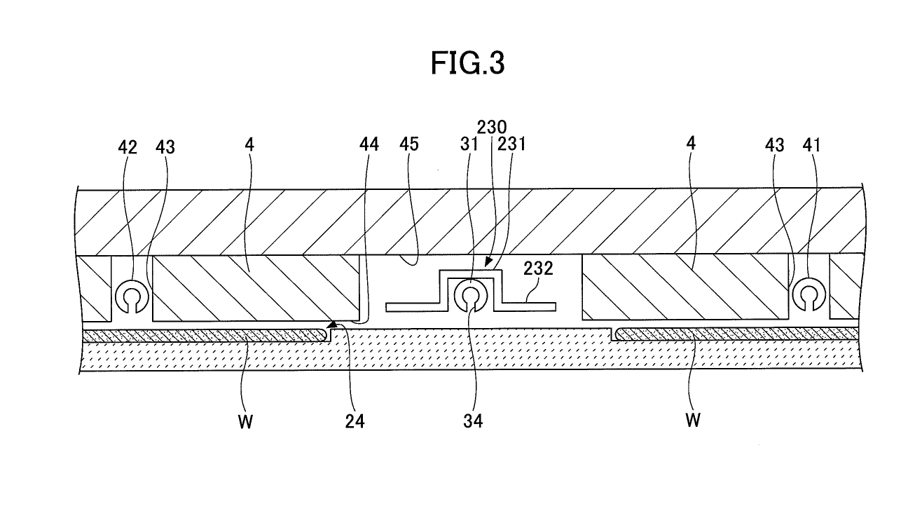

FIG. 3 illustrates a cross-sectional view cut along a concentric circle of the turntable 2 of the film deposition apparatus of the embodiment. More specifically, FIG. 3 illustrates the cross-sectional view from one of the separation area D to the other separation area D by way of the first process area P1.

As shown in FIG. 3, approximately sectorial convex portions 4 are provided on the ceiling plate 11 of the vacuum chamber 1 in the separation areas D. Flat low ceiling surfaces 44 (first ceiling surfaces) that are lower surfaces of the convex portions 4 and ceiling surfaces 45 (second ceiling surfaces) that are higher than the ceiling surfaces 44 provided on both sides of the ceiling surfaces 44 in a circumferential direction, are formed in the vacuum chamber 1.

As illustrated in FIG. 2, the convex portions 4 forming the ceiling surfaces 44 have a sectorial planar shape whose apexes are cut into an arc-like shape. Moreover, each of the convex portions 4 has a groove portion 43 formed so as to extend in the radial direction in the center in the circumferential direction, and each of the separation gas nozzles 41 and 42 is accommodated in the groove portion 43. Here, a periphery of each of the convex portions 4 (a location on the peripheral side of the vacuum chamber 1) is bent into a L-shaped form so as to face an outer end surface of the turntable 2 and to be located slightly apart from the chamber body 12 in order to prevent each of the process gas from mixing with each other.

As illustrated in FIG. 3, a nozzle cover 230 is provided on the upper side of the first process gas nozzle 31 in order to cause the first process gas to flow along the wafer W and so as to cause the separation gas to flow through a location close to the ceiling plate 11 of the vacuum chamber 1 while flowing away from the neighborhood of the wafer W. As illustrated in FIG. 3, the nozzle cover 230 includes an approximately box-shaped cover body 231 whose lower surface side is open to accommodate the first process gas nozzle 31, and current plates 232 having a plate-like shape and connected to the lower open ends of the cover body 231 on both upstream and downstream sides in the rotational direction of the turntable 2. Here, a side wall surface of the cover body 231 on the rotational center side of the turntable 2 extends toward the turntable 2 (i.e., downward) so as to face a tip of the first process gas nozzle 31. In addition, the side wall surface of the cover body 231 on the peripheral side of the turntable 2 is cut off so as not to interfere with the first process gas nozzle 31.

Next, the first plasma generator 80 and the second plasma generator 180 respectively provided above the second and third process gas nozzles 32 and 33 are described below in detail. Here, in the present embodiment, because each of the first plasma generator 80 and the second plasma generator 180 can perform an independent plasma treatment and has a different configuration from each other, each of the first plasma generator 80 and the second plasma generator 180 is independently described below. Hereinafter, the first plasma generator 80 and the second plasma generator 180 may be simply expressed as the “plasma generator 80” and “plasma generator 180” without attaching the language of the “first” and “second” thereto. In this regard, the other components related to the plasma generators 80 and 180 such as radio frequency power sources 85 and 189, and matching boxes 84 and 188 are expressed in a similar manner.

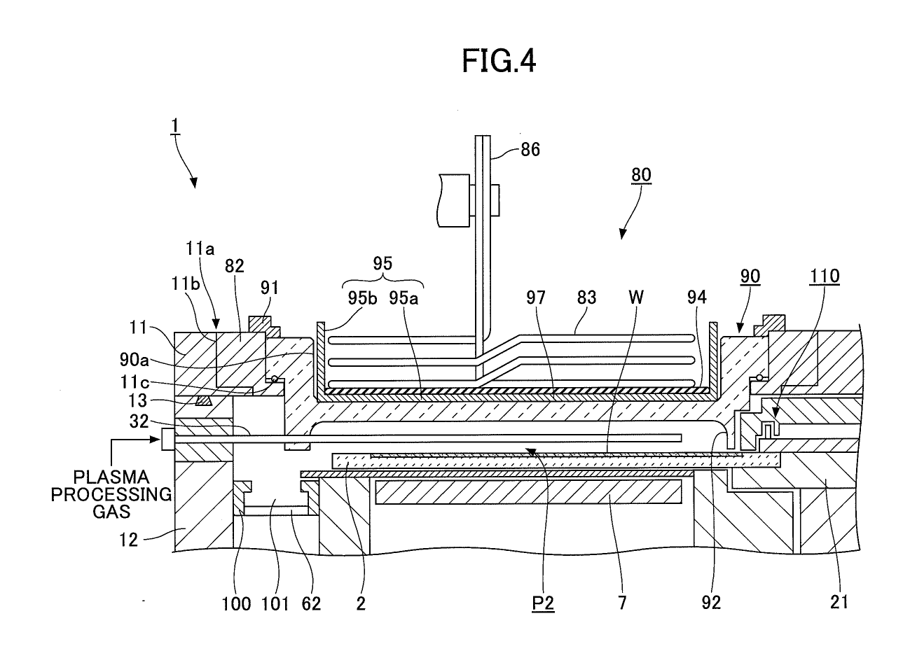

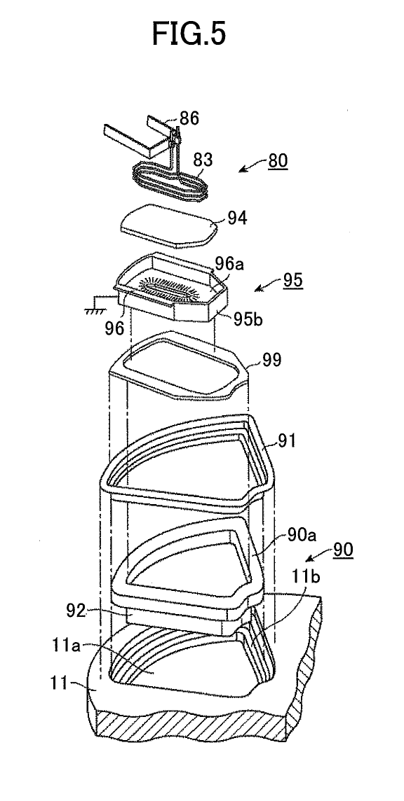

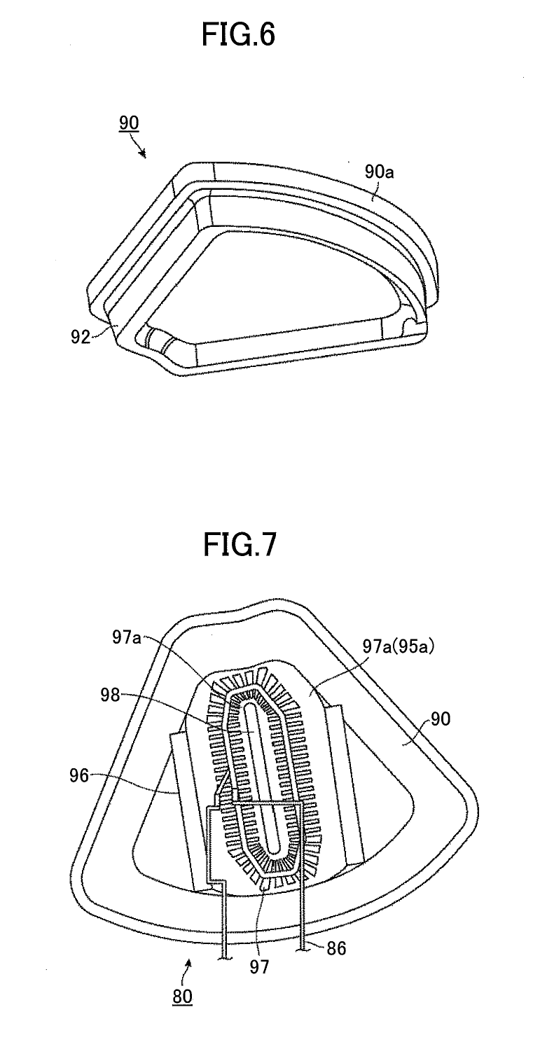

FIG. 4 illustrates a vertical cross-sectional view of an example of the first plasma generators 80 of the plasma processing apparatus according to the first embodiment of the present invention. Also, FIG. 5 illustrates an exploded perspective view of an example of the first plasma generator 80 of the plasma processing apparatus according to the first embodiment of the present invention. Furthermore, FIG. 6 illustrates a perspective view of an example of a housing provided in the first plasma generator 80 of the plasma processing apparatus according to the first embodiment of the present invention.

The first plasma generator 80 is configured to wind an antenna 83 constituted of a metal wire or the like, for example, triply around the vertical axis. Moreover, as illustrated in FIG. 2, the plasma generator 80 is arranged so as to surround a band area extending in the radial direction of the turntable 2 when seen in a plan view and to cross the diameter of the wafer W on the turntable 2.

The antenna 83 is, for example, connected to the radio frequency power source 85 having a frequency of 13.56 MHz and an output power of 5000 W by way of the matching box 84. Then, the antenna 83 is provided to be hermetically separated from an inner area of the vacuum chamber 1. Here, a connection electrode 86 is provided to electrically connect the antenna 83 with the matching box 84 and the radio frequency power source 85.

As illustrated in FIGS. 4 and 5, an opening 11a having an approximately fan-like shape when seen in a plan view, is formed in the ceiling plate 11 above the second process gas nozzle 32.

As illustrated in FIG. 4, an annular member 82 is hermetically provided in the opening 11a along the verge of the opening 11a. The housing 90 described later is hermetically provided on the inner surface side of the annular member 82. In other words, the annular member 82 is hermetically provided at a position where the outer peripheral side of the annular member 82 faces the inner surface 11b of the opening 11a in the ceiling plate 11 and the inner peripheral side of the annular member 82 faces a flange part 90a of the housing 90 described later. The housing 90 made of, for example, a derivative of quartz is provided in the opening 11a through the annular member 82 in order to arrange the antenna 83 at a position lower than the ceiling plate 11.

FIG. 6 is a diagram illustrating an example of the housing 90 of the first plasma generator 80 of the plasma processing apparatus according to the first embodiment of the present invention. As illustrated in FIG. 6, the housing 90 is configured to have a peripheral part horizontally extending along the circumferential direction on the upper side so as to form the flange part 90a and a central part getting recessed inward toward the inner area of the vacuum chamber 1 when seen in a plan view.

The housing 90 is arranged to cross the diameter of the wafer W in the radial direction of the turntable 2 when the wafer W is located under the housing 90. Here, as illustrated in FIG. 4, a seal member 11c such as an O-ring or the like is provided between the annular member 82 and the ceiling plate 11.

An internal atmosphere of the vacuum chamber 1 is sealed by the annular member 82 and the housing 90. More specifically, the annular member 82 and the housing 90 are set in the opening 11a, and then the housing 90 is pressed downward through the whole circumference by a pressing member 91 formed into a frame-like shape along the contact portion of the annular member 82 and the housing 90. Furthermore, the pressing member 91 is fixed to the ceiling plate 11 by volts and the like not illustrated in the drawings. Thus, the internal atmosphere of the vacuum chamber 1 is set to be sealed. Here, in FIG. 5, a depiction of the annular member 82 is omitted for simplification.

As illustrated in FIG. 6, a projection portion 92 vertically extending toward the turntable 2 is formed in a lower surface of the housing 90 so as to surround each of the process areas P2 and P3 under the housing 90 along each circumferential direction thereof. Then, the second process gas nozzle 32 is accommodated in an area surrounded by an inner circumferential surface of the projection portion 92, the lower surface of the housing 90 and the upper surface of the turntable 2. Here, the projection portion 92 at the base end portion (the inner wall side of the vacuum chamber 1) of the second process gas nozzle 32 is cut off so as to be formed into an approximately arc-like form along the outer shape of the second process gas nozzle 32.

As illustrated in FIG. 4, the projection portion 92 is formed on the lower side of the housing 90 along the circumferential direction thereof. The projection portion 92 prevents the seal member 11c from being exposed to the plasma, thereby separating the seal member 11c from the plasma generation space. Because of this, even if the plasma is likely to diffuse, for example, toward the seal member 11c side, because the plasma goes to the seal member 11c by way of the lower side of the projection portion 92, the plasma becomes inactivated before reaching the seal member 11c.

A grounded Faraday shield 95 that is formed so as to approximately fit along an inner shape of the housing 90 and is made of a conductive plate-like body, for example, a metal plate such as a copper plate and the like, is installed in the housing 90. The Faraday shield 95 includes a horizontal surface 95a horizontally formed so as to be along the bottom surface of the housing 90, and a vertical surface 95b extending upward from the outer edge of the horizontal surface 95a through the whole circumference, and may be configured to be approximately hexagon when seen in a plan view.

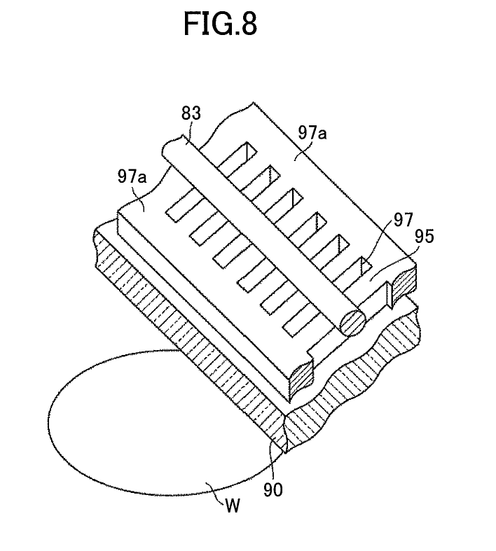

FIG. 7 illustrates a plan view of an example of the first plasma generator 80 according to the present embodiment, and FIG. 8 illustrates a perspective view of a part of the Faraday shield provided in the plasma generator according to the present embodiment.

Upper end edges of the Faraday shield 95 on the right side and the left side extend rightward and leftward, respectively, when seen from the rotational center of the turntable 2 horizontally, and form supports 96. As illustrated in FIG. 5, a frame body 99 is provided between the Faraday shield 95 and the housing 90 to support the support 96 from below and so as to be supported by the flange part 90a of the housing 90 on the central area C side and the outer peripheral side of the turntable 2.

When an electric field generated by the antenna 83 reaches the wafer W, a pattern (electrical wiring and the like) formed inside the wafer W may be electrically damaged. Because of this, as illustrated in FIG. 8, many slits 97 are formed in the horizontal surface 95a in order to prevent an electric field component of the electric field and a magnetic field (i.e., an electromagnetic field) generated by the antenna 83 from going toward the wafer W located below and to allow the magnetic field to reach the wafer W.

As illustrated in FIGS. 7 and 8, the slits 97 are formed under the antenna 83 along the circumferential direction so as to extend in a direction perpendicular to a winding direction of the antenna 83. Here, the slits 97 are formed to have a width dimension equal to or less than about 1/10000 of a wavelength of the high frequency power supplied to the antenna 83. Moreover, electrically conducting paths 97a made of a grounded electric conductor and the like are arranged on one end and the other end in a lengthwise direction of each of the slits 97a so as to stop open ends of the slits 97a. An opening 98 is formed in an area out of the area where the slits 97 are formed in the Faraday shield 95, that is to say, at the central side of the area where the antenna 83 is wound around to be able to observe a light emitting state of the plasma therethrough. Here, in FIG. 2, the slits 97 are omitted for simplicity, and an example of the slit formation area is expressed by alternate long and short dash lines.

As illustrated in FIG. 5, an insulating plate 94 made of quartz and the like having a thickness dimension of, for example, about 2 mm, is stacked on the horizontal surface 95a of each of the Faraday shields 95 in order to ensure insulation properties from the first plasma generator 80 placed on the Faraday shield 95. In other words, the first plasma generator 80 is arranged so as to face the inside of the vacuum chamber 1 (the wafer W on the turntable 2) through the housing 90, the Faraday shield 95 and the insulating plate 94.

Next, a configuration for generating induction plasma from a plasma processing gas is described below in detail.

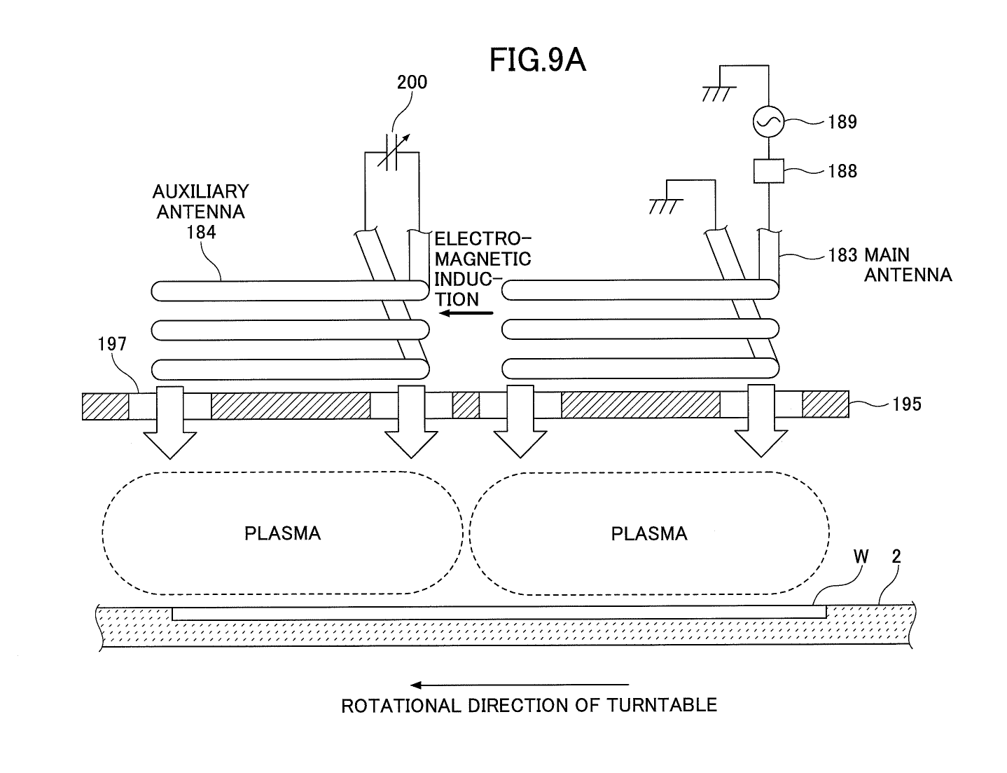

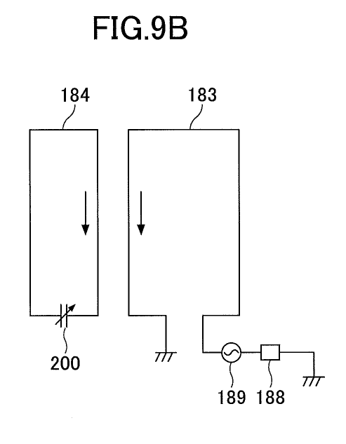

FIGS. 9A and 9B are a schematic configuration diagram and a circuit diagram of an example of the second plasma generator 180. FIG. 9A is the schematic configuration diagram of the example of the second plasma generator 180, and FIG. 9B is the circuit diagram of the example of the second plasma generator 180. FIG. 9A schematically illustrates a characterizing portion of the plasma processing apparatus, and as illustrated, the second plasma generator 180 includes a main antenna 183 connected to the radio frequency power source 189, and an auxiliary antenna (floating coil) 184 that is electrically insulated from the main antenna 183. Moreover, as illustrated in FIG. 9B, plasma is generated throughout an area below the antennas 183 and 184 by electromagnetic induction between the main antenna 183 and the auxiliary antenna 184 without connecting the radio frequency power source 189 to the auxiliary antenna 184. Furthermore, as illustrated in FIG. 9B, a capacitance variable mechanism 200 such as a variable capacitor is connected to the auxiliary antenna 184 and thereby changing the impedance of the auxiliary antenna 184.

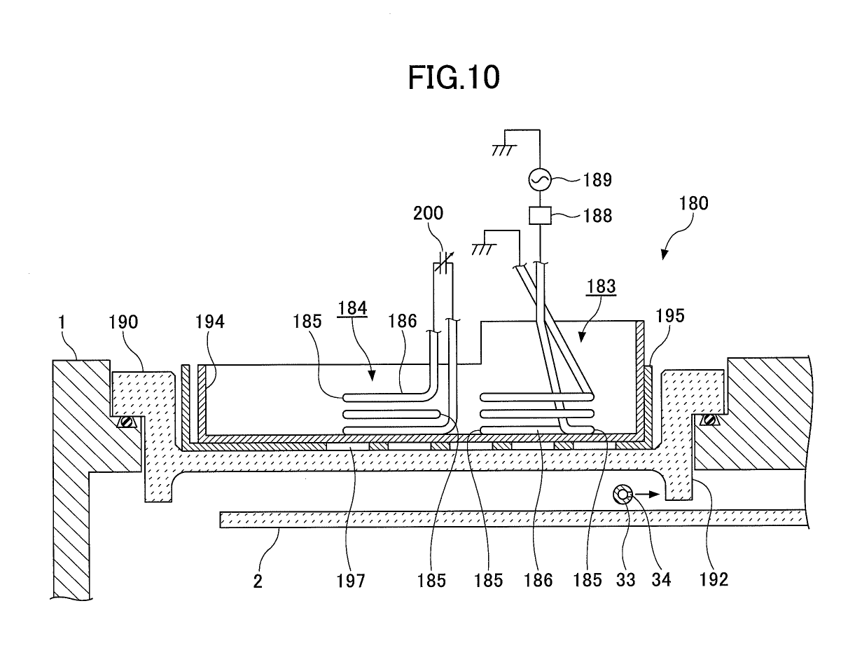

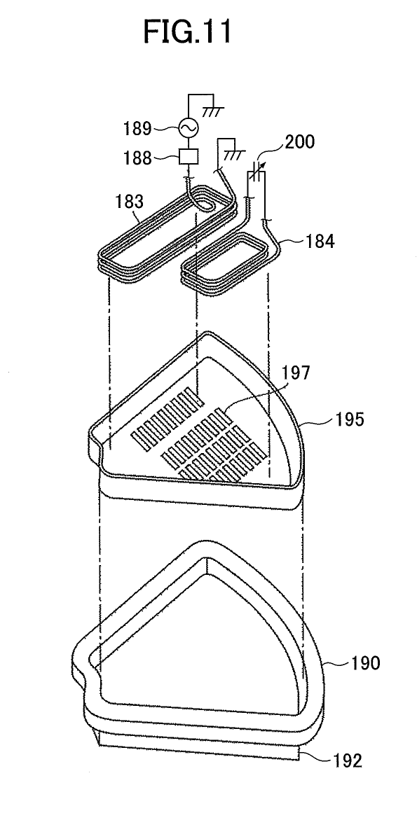

FIG. 10 is a vertical cross-sectional view of an example of the second plasma generator 180, and FIG. 11 is an exploded perspective view of the second plasma generator 180. As illustrated in FIGS. 2, 9 and 10, the main antenna 183 and the auxiliary antenna 184 are disposed above the third process gas nozzle 33, and each of the antennas 183 and 184 is formed by winding a metal wire around the vertical axis in a form of coil. The main antenna 183 is arranged upstream of the auxiliary antenna 184 in the rotational direction of the turntable 2. To begin with, the main antenna 183 is described below.

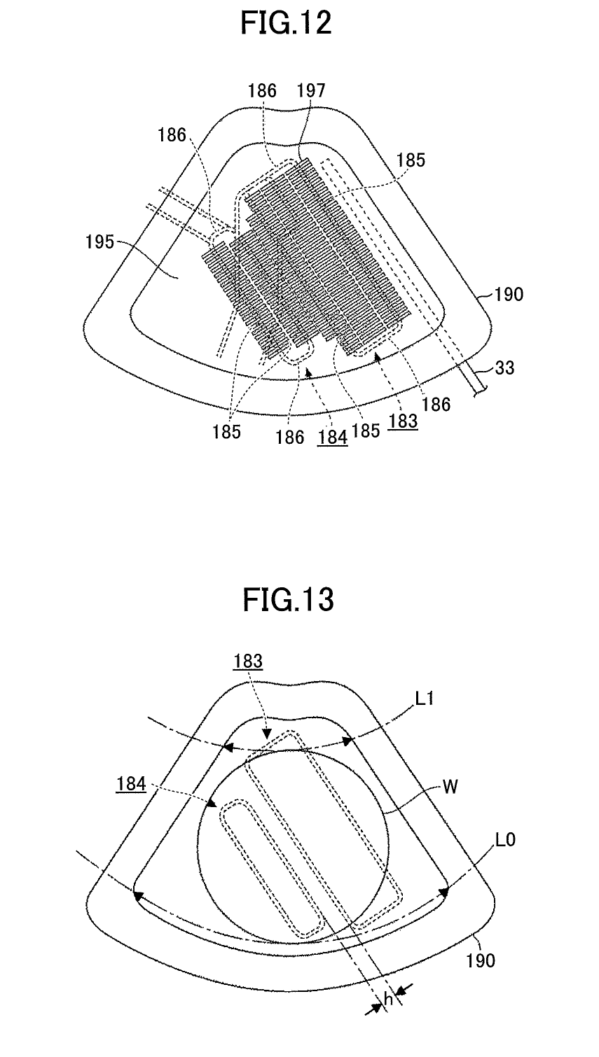

FIG. 12 is a top view of the second plasma generator 180, and FIG. 13 is a plan view illustrating an example of a positional relationship between the antennas 183 and 184 and the wafer W in the second plasma generator 180. As illustrated in FIG. 12, the main antenna 183 is arranged to cross the passing area of the wafer W on the turntable 2 from the central side to the peripheral side when seen in a plan view. In this example, the main antenna 183 is wound to form an approximately rectangular shape as seen in a plan view. In other words, each of the upstream and downstream portions of the main antenna 183 in the rotational direction of the turntable 2, and each of the central and peripheral portions of the main antenna 183 are formed in a linear fashion.

More specifically, when each of the upstream and downstream portions of the main antenna 183 in the rotational direction is referred to as a “straight section,” these straight sections 185 are formed along the radial direction of the turntable 2, in other words, along the lengthwise direction of the third process gas nozzle 33. Also, when each of the central and peripheral portions of the main antenna 183 is referred to as a “connecting portion 186,” each of the connecting portions 186 is formed along a tangential direction of the turntable 2. Then, the straight sections 185 and the connecting portions 186 are connected with each other in series at each end through approximately perpendicularly bending portions, and are connected to the radio frequency power source 189 through the matching box 188. In the present embodiment, the frequency and the output power of the radio frequency power source 189 are set at 13.56 MHz and 5000 W, respectively.

As illustrated in FIG. 12, the upstream straight section 185 in the rotational direction of the turntable 2 of two of the straight sections 185 is disposed at a position slightly apart from and downstream of the third process gas nozzle 33 in the rotational direction of the turntable 2. In FIGS. 12 and 13, the antennas 183 and 184 are depicted by dashed lines, and the wafer W is depicted by a solid line.

The auxiliary antenna 184 is arranged downstream of and close to the main antenna 183 in the rotational direction of the turntable 2, and is electrically insulated from the main antenna 183. Accordingly, projection areas of the antennas 183 and 184 as seen in a plan view are arranged so as not to overlap each other. Moreover, the auxiliary antenna 184 is arrange to surround a rectangular area slightly smaller than the main antenna as seen in a plan view, and is provided to have approximately the same distance from the rotational center of the turntable and from the outer edge of the turntable 2.

In addition, with respect to the auxiliary antenna 184, the upstream and downstream straight sections 185 are arranged along the third process gas nozzle 33 in a line form. Each of the connecting portions 186 of the auxiliary antenna 184 on the rotational center side and the peripheral side of the turntable 2 is arranged along the tangential direction of the turntable 2. Hence, the straight sections 185 of the main antenna 183 and the straight sections 186 of the auxiliary antenna 184 are parallel with each other.

As illustrated in FIG. 13, a distance h between the upstream straight section 185 in the auxiliary antenna 184 in the rotational direction of the turntable 2 and the downstream straight section 185 of the main antenna 183 is set at a dimension that the radio frequency electric field from the main antenna 83 can reach the auxiliary antenna 184. The distance h is specifically set in a rage of 2 to 30 mm.

More specifically, when the radio frequency power is supplied to the main antenna 183, a radio frequency electric field is generated around an axis in an extending direction of the main antenna 183 due to a radio frequency current flowing through the main antenna 183. Then, the auxiliary antenna 184 is not connected to the radio frequency power source 189, and is in a floating state in which the auxiliary antenna 184 is electrically insulated from the main antenna 183. Accordingly, an inducted electromotive force is generated in the auxiliary antenna 184, and an inducted current flows through the auxiliary antenna 184 due to the electromagnetic induction between the main antenna 183 and the auxiliary antenna 184 caused by the radio frequency electric field formed around the main antenna 183.

Here, a magnitude of the inducted current flowing through the auxiliary antenna 184 is investigated. A resonant frequency f (Hz) is expressed by the following formula.

f=1/(2π√(L×C))

Here, f expresses a frequency of the radio frequency power supplied to the main antenna 183 (auxiliary antenna 184); L expresses an inductance (H) of the auxiliary antenna 184; and C expresses a capacitance value (F) of the auxiliary antenna 184. The following formula is obtained by converting the above formula to a formula that expresses the capacitance value C.

C=1/(47π²×f²×L)

Then, when the frequency f and the inductance L are made, for example, 13.56 MHz and 2.62 μH, respectively, and assigned to the above formula, the capacitance value C that causes a series resonance in the auxiliary antenna 184 is about 52.6 pF. In other words, when the capacitance value C of the auxiliary antenna 184 is 52.5 pF, the series resonance occurs in the auxiliary antenna 184 due to the radio frequency electric field travelling to the auxiliary antenna 184 from the main antenna 183, and plasma is generated not only in an area under the main antenna 183 but also in an area under the auxiliary antenna 184. Therefore, in the present embodiment, the auxiliary antenna 184 is configured to generate resonance in the auxiliary antenna 184, and further to be able to adjust a state of the resonance.

More specifically, as illustrated in FIGS. 9A through 11, a capacitance variable mechanism 200 constituted of a variable capacitor and the like for adjusting the capacitance value C of the auxiliary antenna 184 is provided in the auxiliary antenna 184 as an impedance adjustment unit. More specifically, one end or the other end of both terminals of the capacitance variable mechanism 200 is connected to one end side or the other end side in a length direction of the auxiliary antenna 184 so that the capacitance variable mechanism 200 is disposed within the loop of the auxiliary antenna 184. Then, a drive mechanism (not illustrated in the drawings) constituted of a motor and the like is connected to the capacitance variable mechanism 200, and is configured to adjust the capacitance value of the capacitance variable mechanism 200 (auxiliary antenna 184) by operating the drive mechanism.

A configuration example of such a capacitance variable mechanism 200 and a drive unit is described below. For example, a pair of opposite electrodes (not illustrated in the drawings) is provided in the capacitance variable mechanism 200, and the drive mechanism is connected to one of the pair of opposite electrodes. The drive mechanism changes a distance between the pair of opposite electrodes by moving one of the pair of opposite electrodes, thereby adjusting the capacitance value of the capacitance variable mechanism 200, which is, in other words, the capacitance value of the auxiliary antenna 184. Then, when the currents flow through the main antenna 183 and the auxiliary antenna 184 in the opposite direction to each other due to the impedance of the auxiliary antenna 184 as seen in a plan view, as illustrated in FIG. 9B, the direction of the currents are determined so that the currents flowing through the antennas 183 and 184 are superimposed on each other (not canceled out each other). The adjustment of the capacitance value C (drive of the drive mechanism) is performed by a control signal from a control unit 120 described later. A variable range of the capacitance value C of the capacitance variable mechanism 200 is, for example, lower than or equal to 50 pF, and a variable range of the capacitance value C of the entire auxiliary antenna 184 is from 50 to 500 pF.

The antennas 183 and 184 described above are arranged so as to be hermetically separated from the inner area of the vacuum chamber 1 similar to the antenna 83 in the first plasma generator 80. The ceiling plate 11 above the third process gas nozzle 32 has an approximately fan-shaped opening as seen in a plan view, and the opening is hermetically closed by a housing 190, for example, made of quartz. Because the configuration of the housing 90 and a method of fixing the housing 190 to the ceiling plate 11 are similar to those of the housing 90 described with the first plasma generator 80, the description is omitted.

Next, an auxiliary plasma process performed by the second plasma generator 180 on an area where the degree of reaction is low after the wafer W passes through the first plasma generator 80 is described below. The wafer W revolves due to the rotation of the turntable 2 and passes through the areas P1, P2 and P3 under the process gas nozzles 31, 32 and 33, respectively. Because of this, in the wafer W on the turntable 2, the speeds (angular rates) when passing through the areas 21, P2 and P3 differ from each other at the edge on the rotational center side and at the edge on the peripheral side of the turntable 2. More specifically, when the diameter dimension of the wafer W is 300 mm (12 inches), the speed at the edge on the rotational center side is one third as fast as that of the edge on the peripheral side.

More specifically, when a distance from the rotational center of the turntable 2 to the edge of the wafer W on the rotational center side is expressed by “s, ” the circumference DI of a circle on which the edge of the wafer W on the rotational center side passes equals to (2×π×s). In the meantime, under the same condition as the above, the circumference DO of a circle on which the edge of the wafer W passes equals to (2×π×(s+300)). On this occasion, the wafer W moves the circumferences DI and DO for the same period of time by the rotation of the turntable 2. Hence, when speeds of the edges of the wafer W on the rotational center side and the peripheral side are expressed by VI and VO, respectively, a ratio R (VI÷VO) of VI to VO of the speeds equals to (s÷(s+300)). Then, when the distance s is 150 mm, the ratio R equals to ⅓.

Accordingly, when plasma whose reactivity with a component of a source gas adsorbed on the wafer W is not very high, is used, a degree of reaction of the source gas with a reaction gas is liable to be lower on the peripheral side of the wafer W than on the central side if the reaction gas is merely converted to plasma in the vicinity of the second process gas nozzle 32.

Therefore, in order to correct such a disproportion of the degree of reaction, the plasma processing apparatus according to the first embodiment of the present invention is configured to be able to locally generate plasma in any area in the radial direction of the turntable 2, thereby correcting the disproportion of the degree of reaction and improving uniformity of a film thickness and film quality across the surface of the wafer W. As discussed above, with respect to the local plasma generation, the generation area of plasma can be controlled by changing a reactance by the capacitance variable mechanism 200 connected to the auxiliary antenna 200, thereby changing the impedance of the auxiliary antenna 184.

In addition to that, a shape of the projection portion 92 is adjusted in order to perform a uniform plasma process on the wafer W. More specifically, as illustrated in FIG. 13, lengths of the process area P3 where the edge of the wafer W on the rotational center side and the edge of the wafer W on the peripheral side of the turntable 2 pass are expressed as LI and LO, respectively, the ratio of LI to LO (LI÷LO) equals to ⅓. In other words, a shape of the projection portion 92 (dimension of the process area P3) is set depending on a speed at which the wafer W on the turntable 2 passes through the process area P3. Moreover, as described later, the plasma process is uniformly performed on the surface of the wafer W there across because the process area P3 is filled with the plasma of ammonia gas.

As illustrated in FIGS. 4 and 9A through 13, a Faraday shield 195 is arranged between the housing 190 and the antennas 183 and 184 in order to prevent an electric field component of an electromagnetic field generated in the antennas 183 and 184 from going downward and to allow a magnetic field of the electromagnetic field to pass through downward. More specifically, the Faraday shield 195 is formed into an approximately box-like shape with an opening on the upper side, and is made of a metal plate (conductive plate) that forms a conductive plate-like body, and grounded to block the electric field. The Faraday shield 195 includes slits 197 that form rectangular openings in the bottom surface, which is made of the metal plate, in order to allow the magnetic field to pass therethrough.

Each of the slits 197 is not in communication with other adjacent slits 197. In other words, the metal plate that forms the Faraday shield 196 surrounds each of the slits 197 and extends in the circumferential direction. The slits 197 are formed in a direction perpendicular to the lengthwise direction of the antennas 183 and 184, and are arranged at a plurality of locations at equal distances from each other along the lengthwise direction of the antennas 183 and 184 under the antennas 183 and 184. The slits 197 are not formed in a position right above the third process gas nozzle 33, thereby preventing the plasma processing gas in the process gas nozzle 33 from converting to plasma.

As illustrated in FIGS. 11 and 12, while the slits 197 are formed at locations under the straight sections 185 of the antennas 183 and 184, the slits 197 are not formed at locations under the straight sections 186 including corners connecting the straight sections 186 with the straight sections 185 while bending at both ends of the straight sections 185. If the slits 197 are formed along the circumferential direction of the antennas 183 and 184, at the portions where the antennas 183 and 184 bend (R portions), the slits 197 are arranged so as to bend along the antennas 183 and 184. However, at the bending portions, the slits 197 adjacent to each other are liable to be in communication with each other in an area inside to antennas 183 and 184, which decreases an effect of blocking the electric field component. On the other hand, if the widths of the slits 197 are formed narrow at the bending portions so as not to be in communication with each other, an amount of the magnetic field component going toward the wafer W decreases more greatly than the amount of the magnetic field component of the straight sections 185. Furthermore, if the distance between the slits 197 adjacent to each other are increased at an area outside the antennas 183 and 184, even the electric field component together with the magnetic field component may go toward the wafer W, which is liable to damage the wafer W by electric charge.

Therefore, in the present embodiment, in order to equalize the amount of magnetic field component going toward the wafer W from the main antenna 183 through each the slits 197, the straight sections 185 of the antenna 183 are arranged across the position through which the wafer W passes, and the slits 197 are formed under the straight sections 185. Moreover, the slits 197 are not formed under the bending portions extending from the both ends of the straight sections 185, and the conductive plate that forms the Faraday shield 195 is arranged, thereby blocking not only the electric field component but also the magnetic field component. Thus, the generated amount of plasma is made uniform in the radial direction of the turntable 2.

Hence, the slit 197 at any position is seen, the opening width of the slit 197 is uniform along the lengthwise direction of the slit 197. Then, the opening widths of the slits 197 are adjusted to be made the same as the other slits 197 in the Faraday shield 197.

An insulating member 194, for example, made of quartz is provided between the Faraday shield 195 and the antennas 183 and 184 described above in order to insulate the Faraday shield 195 from the antennas 183 and 184. The insulating member 194 is formed into an approximately box-like shape with an opening on the upper side. In FIG. 13, the Faraday shield 195 is omitted to show the positional relationship between the antennas 183 and 184 and the wafer W. In the drawings other than FIG. 10, the depiction of the insulating member 194 is omitted. The other components of the plasma processing apparatus according to the present invention are described below again.

As illustrated in FIGS. 1 and 2, a side ring 100 that forms a cover body is arranged at a position slightly lower than the turntable 2 and outer edge side of the turntable 2. Exhaust openings 61 and 62 are formed in an upper surface of the side ring 100 at two locations apart from each other in the circumferential direction. In other words, two exhaust ports are formed in a bottom surface of the vacuum chamber 1, and the exhaust openings 61 and 62 are formed at locations corresponding to the exhaust ports in the side ring 100.

In the present specification, one of the exhaust openings 61 and 62 is referred to as a first opening 61 and the other of the exhaust openings 61 and 62 is referred to as a second opening 62. Here, the first exhaust opening 61 is formed between the separation gas nozzle 42 and the first plasma generator 80 located on the downstream side of the separation gas nozzle 42 in the rotational direction of the turntable 2. Furthermore, the second exhaust opening 62 is formed between the second plasma generator 180 and the separation area D on the downstream side of the second plasma generator 180 in the rotational direction of the turntable 2.

The first exhaust opening 61 is provided to evacuate the first process gas and the separation gas, and the second exhaust opening 62 is provided to evacuate the plasma processing gas and the separation gas. Each of the first exhaust opening 61 and the second exhaust opening 62 is, as illustrated in FIG. 1, connected to an evacuation mechanism such as a vacuum pump 64 through an evacuation pipe 63 including a pressure controller 65 such as a butterfly valve.

As described above, because the housings 90 and 190 are arranged from the central area C side to the outer peripheral side, a gas flowing from the upstream side in the rotational direction of the turntable 2 to the plasma process area P2 and P3 may be blocked from going to the evacuation opening 62 by the housings 90. In response to this, a groove-like gas flow passage 101 (see FIGS. 1 and 2) is formed in the upper surface of the side ring 100 on the outer edge side of the housing 90 to allow the gas to flow therethrough.

As shown in FIG. 1, in the center portion on the lower surface of the ceiling plate 11, a protrusion portion 5 is provided that is formed into an approximately ring-like shape along the circumferential direction continuing from the central area C side of the convex portion 4 so as to have a lower surface formed as high as the lower surface of the convex portion 4 (ceiling surface 44). A labyrinth structure 110 is provided closer to the rotational center side of the turntable 2 than the protrusion portion 5 and above the core portion 21 to suppress the various gases from mixing with each other in the center area C.

As discussed above, because the housings 90 and 190 are formed at the location close to the central area C, the core portion 21 supporting the central portion of the turntable 2 is formed on the rotational center side so that a portion on the upper side of the turntable 2 is arranged apart from the housing 90. Due to this, the various gases are more likely to mix with each other at the central area C side than at the outer peripheral side. Hence, by forming the labyrinth structure 110 above the core portion 21, a flow path can be made longer to be able to prevent the gases from mixing with each other.

More specifically, the labyrinth structure 110 has a wall part vertically extending from the turntable 2 toward the ceiling plate 11 and a wall part vertically extending from the ceiling plate 11 toward the turntable 2 that are formed along the circumferential direction, respectively, and are arranged alternately in the radial direction of the turntable 2. In the labyrinth structure 110, for example, a first process gas discharged from the first process gas nozzle 31 and heading for the central area C needs to go through the labyrinth structure 110. Due to this, the first process gas decreases in speed with the decreasing the distance from the central area C and becomes unlikely to diffuse. As a result, the first process gas is pushed back by the separation gas supplied to the central area C before reaching the central area C. Moreover, other gases likely to head for the central area C are difficult to reach the central area C by the labyrinth structure 110 in a similar way. This prevents the process gases from mixing with each other in the central area C.

On the other hand, the separation gas supplied from the separation gas supply pipe 51 is likely to diffuse swiftly in the circumferential direction at first, but decreases in speed as going through the labyrinth structure 110. In this case, nitrogen gas is likely to intrude into a very narrow area such as a gap between the turntable 2 and the projection portion 92, but flows to a relatively large area such as an area where the transfer arm 10 moves in and out of the vacuum chamber 1 because the labyrinth structure 110 decreases the flowing speed thereof. Because of this, nitrogen gas is prevented from flowing into a space under the housings 90 and 190.

As illustrated in FIG. 1, a heater unit 7 that is a heating mechanism is provided in a space between the turntable 2 and the bottom part 14 of the vacuum chamber 1. The heater unit 7 is configured to be able to heat the wafer W on the turntable 2 through the turntable 2 up to, for example, a range from room temperature to about 760 degrees C. Furthermore, as illustrated in FIG. 1, a side cover member 71a is provided on a lateral side of the heater unit 7, and an upper covering member 7a is provided so as to cover the heater unit 7 from above. In addition, purge gas supply pipes 73 for purging a space in which the heater unit 7 is provided are provided in the bottom part 14 of the vacuum chamber 1 under the heater unit 7 at multiple locations along the circumferential direction.

As illustrated in FIG. 2, a transfer opening 15 is provided in the side wall of the vacuum chamber 1 to transfer the wafer W between a transfer arm 10 and the turntable 2. The transfer opening 15 is configured to be hermetically openable and closeable by a gate valve G.

The wafer W is transferred between the concave portion 24 of the turntable 2 and the transfer arm 10 at a position where the concave portion 24 of the turntable 2 faces the transfer opening 15. Accordingly, lift pins and an elevating mechanism that are not illustrated in the drawings are provided at a position under the turntable 2 corresponding to the transferring position to lift the wafer W from the back surface by penetrating through the concave portion 24.

Moreover, as illustrated in FIG. 1, a control unit 120 constituted of a computer to control operation of the whole apparatus is provided in the plasma processing apparatus of the present embodiment. A program to implement the substrate process described later is stored in a memory of the control unit 120. This memory stores the program to perform the substrate process described later. This program is constituted of instructions of step groups to cause the apparatus to implement operations described later, and is installed into the control unit 120 from a memory unit 121 that is a storage medium such as a hard disk, a compact disc, a magnetic optical disk, a memory card and a flexible disk.

### WORKING EXAMPLES

Next, working examples performed to check that plasma can be generated in any area by the second plasma generator 190, are described below.

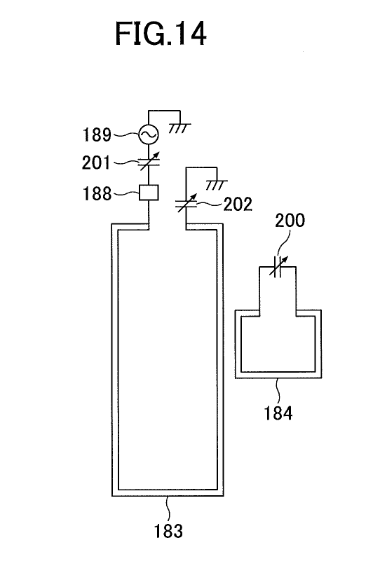

As shown in FIG. 14, these working examples were performed by arranging the main antenna 183 formed into an approximately rectangular shape as seen in a plan view, and the auxiliary antenna 184 formed into an approximately quadrilateral shape at a position close to the main antenna 183 in an experimental chamber. In this example, a capacitance variable mechanism 201 is arranged between one end of the main antenna 183 in the lengthwise direction of the main antenna 183 and the radio frequency power source 189, and a capacitance variable mechanism 202 is also arrange between the other end of the main antenna 183 and the earth so that a capacitance value of the main antenna 183 is adjustable. Moreover, as discussed above, the capacitance variable mechanism 200 is provided in the auxiliary antenna 184.

Then, the capacitance value of the capacitance variable mechanism 200 of the auxiliary antenna 184 was variously changed as the following working examples 1 through 4 in TABLE 1, and current values flowing through the antennas 183 and 184 were measured. Then, plasma was generated in the chamber under the conditions of each of the working examples 1 through 4, and emitting states of the plasma were photographed. In the working examples, a mixed gas of argon (Ar) and oxygen (O₂) was used as the plasma processing gas.

TABLE 1

| | WORKING | WORKING | WORKING | WORKING |
|---|---|---|---|---|
| | EXAMPLE 1 | EXAMPLE 2 | EXAMPLE 3 | EXAMPLE 4 |
| CAPACITANCE VALUE | 11 | 144 | 115 | 126 |
| OF CAPACITANCE | | | | |
| ADJUSTMENT UNIT | | | | |
| (pF) | | | | |
| CURRENT VALUE OF | 21.4 | 21.2 | 17.1 | 5.0 |
| MAIN ANTENNA ON | | | | |
| POWER SOURCE SIDE | | | | |
| (A) | | | | |
| CURRENT VALUE OF | 0.5 | 13.6 | 14.9 | 29.3 |
| AUXILIARY ANTENNA | | | | |
| (A) | | | | |

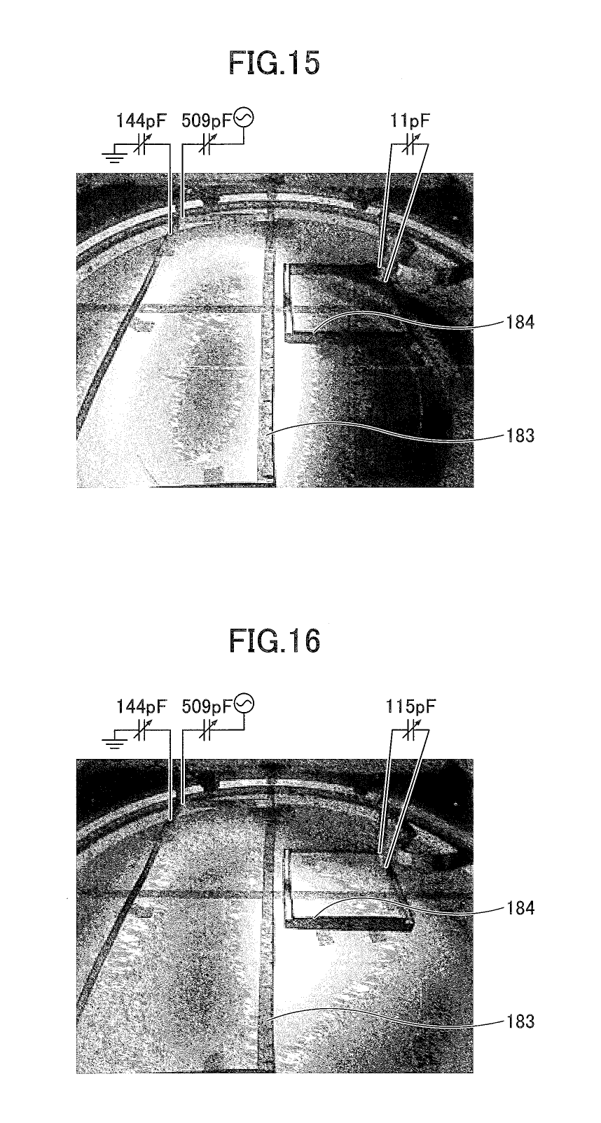

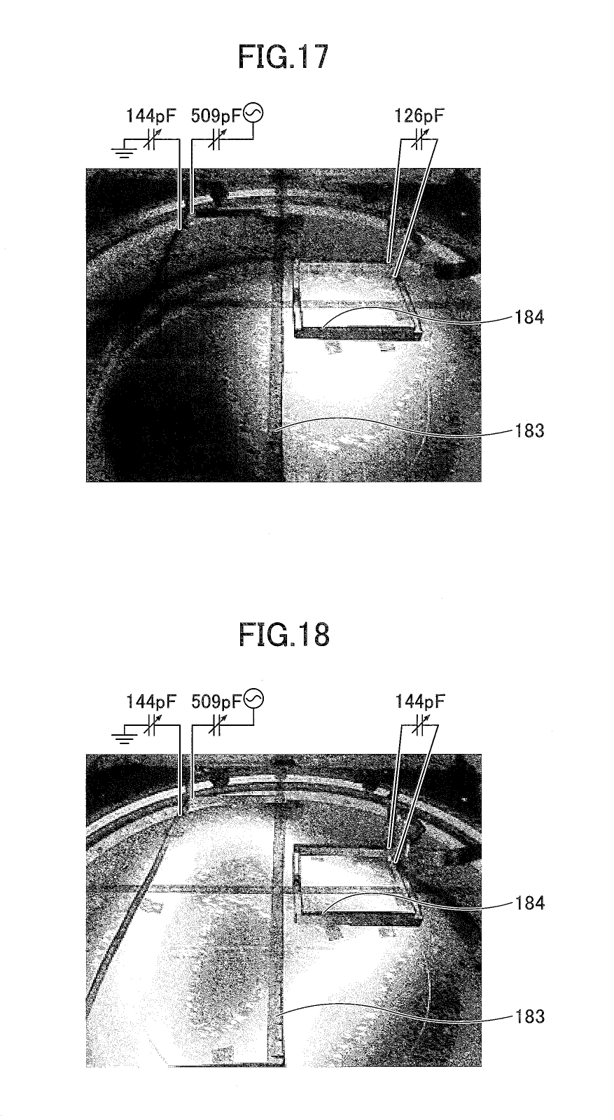

FIGS. 15 through 18 show emitting states of plasma of the working examples 1, 3, 4 and 2, respectively. As a result, as shown in FIGS. 15 through 18, the emitting distribution of plasma changes depending on the capacitance value of the capacitance variable mechanism 200. FIGS. 15 through 18 show that the plasma generation area (areas look white in FIGS. 15 through 18) moves from a position under the main antenna 180 toward a position under the auxiliary antenna 183 in order of increasing figure number. More specifically, in FIG. 15, the plasma was mainly generated at a position under the main antenna 183. In FIG. 16, the plasma was generated along the outer periphery of the main antenna 183 and the auxiliary antenna 184 so as to cross the antennas 183 and 184. In FIG. 17, the plasma was intensely generated at a position where the antennas 183 and 184 faced with each other, and weakened gradually toward the main antenna 183 and the auxiliary antenna 184 from the position. In FIG. 18, the plasma was mainly generated at a position under the auxiliary antenna 184.

Moreover, as put down in TABLE 1 with the capacitance value, the current values flowing through the main antenna 183 and the auxiliary antenna 184 also changed depending on the emitting states of plasma in FIGS. 15 through 18. More specifically, the current value of the main antenna 183 decreased in order of increasing figure number, while the current value of the auxiliary antenna 183 increased. As shown in the result of the working examples, the plasma under the main antenna 183 can be expanded so as to cross the area under the auxiliary antenna 184 (FIGS. 16 and 17). Furthermore, for example, at the start of a film deposition process, when plasma is desired to be generated quickly, it is possible to generate locally intense plasma at a position under the main antenna 183 (FIG. 15).

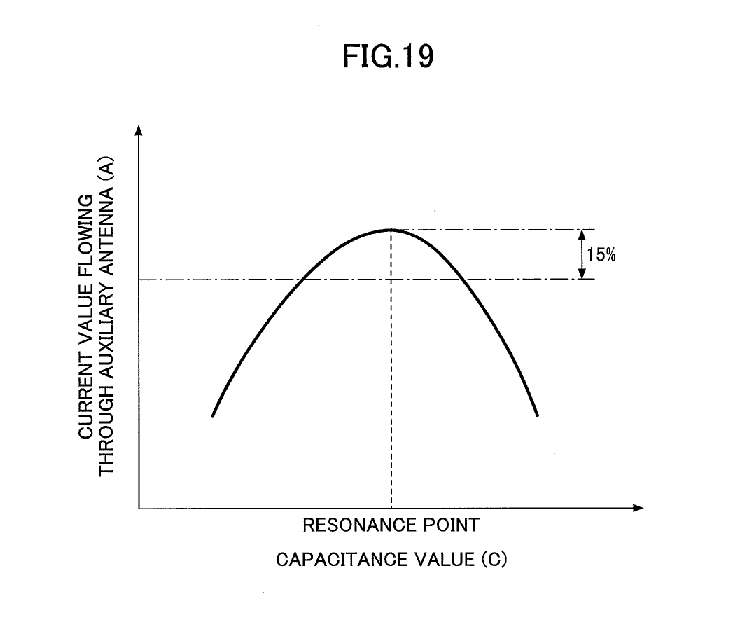

FIG. 19 shows a curve that schematically illustrates the correlation between the capacitance value of the capacitance variable mechanism 200 and the value of the radio frequency current flowing through the auxiliary antenna 184 discussed above. In FIG. 19, the horizontal axis indicates the capacitance value, and the vertical axis indicates the value of the radio frequency current. This curve forms a quadratic curve that is convex upward, and the current value flowing through the auxiliary antenna 184 peaks when the capacitance value becomes a resonance point that causes the series resonance between the main antenna 183 and the auxiliary antenna 184. As discussed above, in order to generate the extended plasma across the antennas 183 and 184, the capacitance value of the capacitance variable mechanism 200 is preferably set at a value that makes the current value flowing through the auxiliary antenna 184 as high as possible. More specifically, the capacitance value is preferably set at a value that can obtain a current value equal to or more than 85% of the current value that causes the series resonance between the antennas 183 and 184.

The plasma can be generated in a desired area of the concave portion 24 on which the wafer W is placed by utilizing the properties. More specifically, when a disproportion of a degree of reaction and a film thickness occur caused thereby in the first plasma generator 80, the second plasma generator 180 generates plasma at a location where the degree of reaction is low, thereby performing a modification process for correcting the disproportion of the degree of reaction. Thus, the uniformity of film thickness, film quality and coverage properties across the wafer W can be enhanced.

[Film Deposition Method]

Next, a film deposition method according to a first embodiment of the present invention is described below.

To begin with, in carrying wafers W into the vacuum chamber 1, the gate valve G is opened. Then, the wafers W are placed on the turntable 2 by the transfer arm 10 through the transfer opening 15 while rotating the turntable 2 intermittently.

Next, the gate valve G is closed and the wafers W are heated to a predetermined temperature by the heater unit 7. Subsequently, the first process gas is discharged from the first process gas nozzle 31 at a predetermined flow rate, and plasma processing gases are supplied from the second process gas nozzle 32 and the third process gas nozzle 33 at predetermined flow rates, respectively.

The inside of the vacuum chamber 1 is adjusted to a predetermined pressure by the pressure controller 65. The radio frequency power sources 85 and 189 supply radio frequency power of predetermined outputs to antennas 83 and 183, respectively.

The first process gas adsorbs on each surface of the wafers W in the first process area P1 by the rotation of the turntable 2. The wafers W on which the first process gas adsorbs pass through the separation area D by the rotation of the turntable 2. In the separation area D, the separation gas is supplied to each of the surfaces of the wafers W, and unnecessary physically absorbed materials with respect to the first process gas are removed.

The wafers W subsequently pass through the second process area P2 by the rotation of the turntable 2. In the second process area P2, a reaction gas supplied from the second process gas nozzle 32 is converted to plasma, and is supplied to each of the surfaces of the wafers W. The reaction gas reacts with the source gas (first process gas) adsorbed on each of the surfaces of the wafer W, and produces a reaction product, a molecular layer of which is deposited on each of the surfaces of the wafers W.

Next, the wafers W having passed through the second process area P2 pass through the third process area P3 by the rotation of the turntable 2. In the third process area P3, a reaction gas supplied from the third process gas nozzle 33 is converted to plasma in a desired area, thereby correcting a disproportion of a degree of reaction in the second process area P2. In general, because angular rates differ from each other on the central side and the peripheral side of the turntable 2, and because the supply of the reaction gas and the reaction with the source gas are likely to be insufficient, a current flowing through the main antenna 183 and an inducted current flowing through the auxiliary antenna 184 are adjusted so that the reaction gas on the peripheral side is converted to plasma. Thus, the plasma process insufficient in the second process area P2 can be complemented, and the disproportion can be corrected.

The wafers W processed by using the plasma pass through the separation area D by the rotation of the turntable 2. The separation area D is an area to separate the first process area P1 from the third process area P3 so that the unnecessary purge gas and the modifying gas do not intrude into the first process area P1.

In the present embodiment, by keeping the turntable 2 rotating, the adsorption of the first process gas on the wafers W, the reaction of the reaction gas with the first process gas adsorbed on the wafers W, and the plasma modification to the area where the reaction is insufficient are performed in this order many times. In other words, the film deposition process by ALD and the modification process of the deposited film are performed many times by rotating the turntable 2.

Here, in the plasma processing apparatus of the present embodiment, the separation areas D are arranged between the process areas P1 and P2 on both sides in the circumferential direction of the turntable 2. Because of this, in the separation areas D, each of the process gas and the plasma processing gases flows toward each of the exhaust openings 61 and 62 while being prevented from mixing with each other.

Next, in the film deposition method according to the first embodiment of the present invention, a process of filling a recessed pattern formed in a wafer W with a SiO₂ film by using an organic aminosilane gas as a source gas is described below.

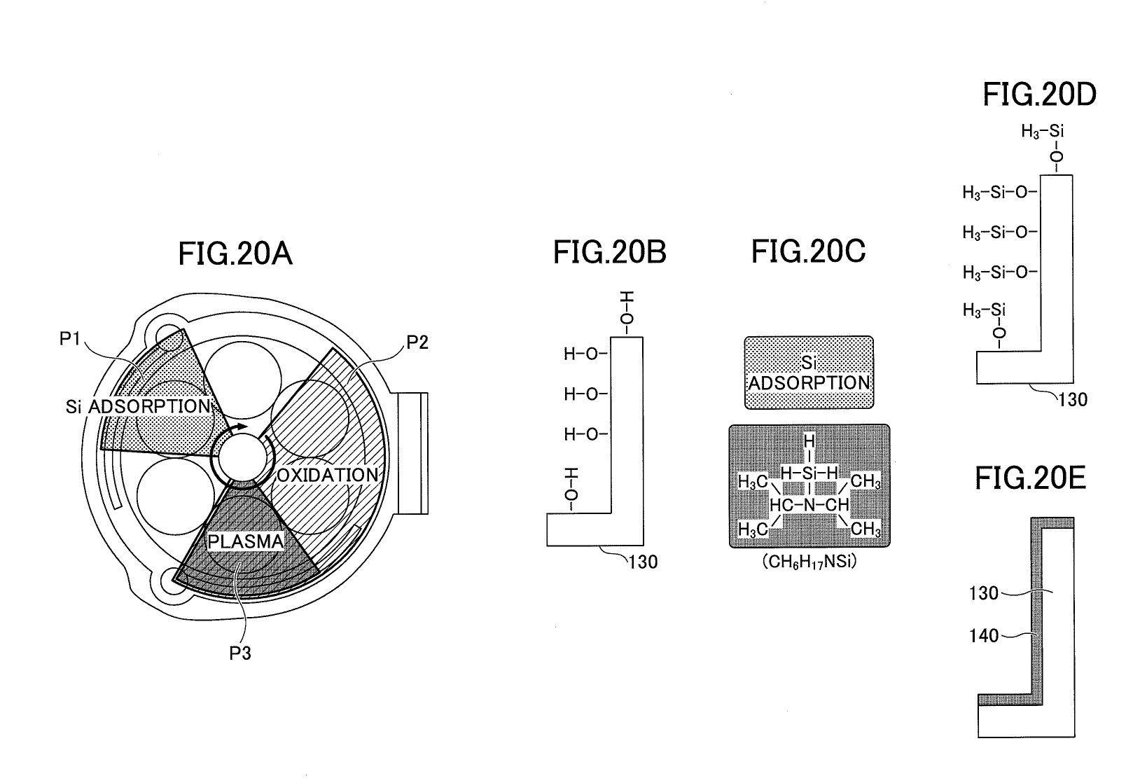

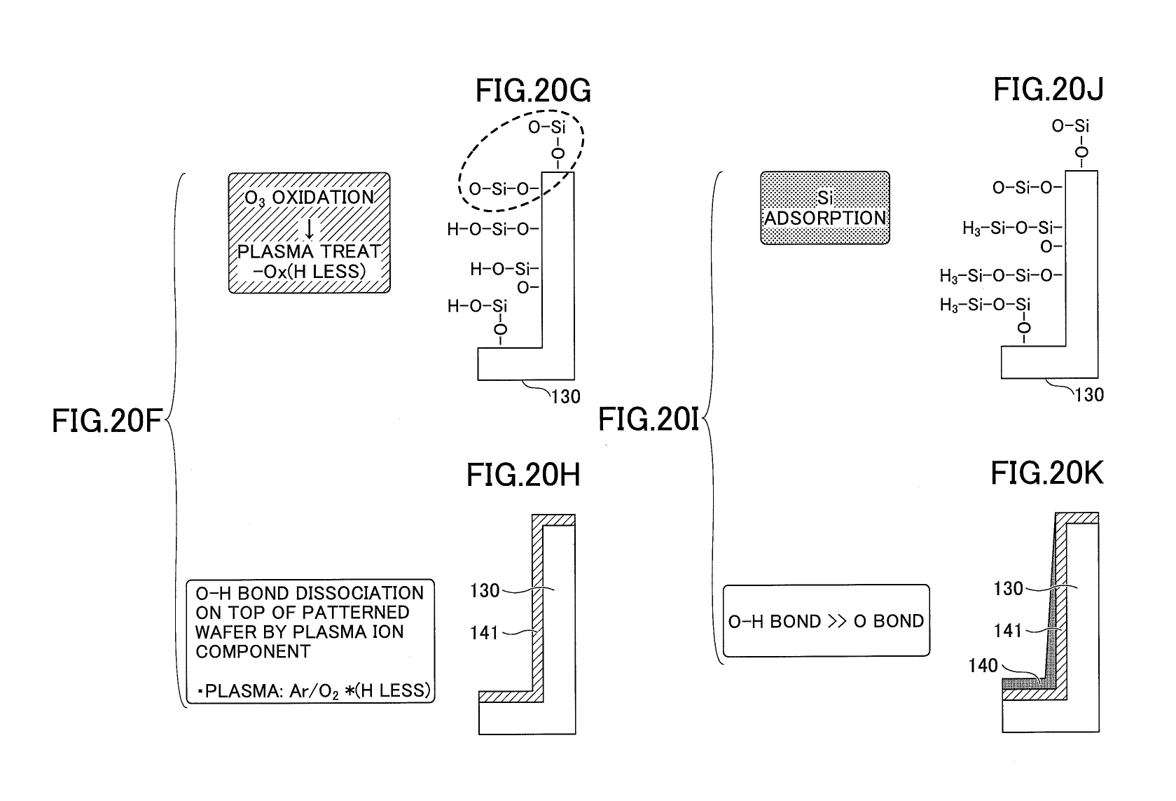

FIGS. 20A through 20K are diagrams for explaining the SiO₂ filling process using the organic aminosilane gas by the film deposition method according to the first embodiment of the present invention.

FIG. 20A is a diagram illustrating an example of the plasma processing apparatus according to the first embodiment of the present invention. The plasma processing apparatus illustrated in FIG. 20A is the same as the plasma processing apparatus described above, and includes the first through third process areas P1 through P3 and the first and second plasma generator 80 and 180.

FIG. 20B is a diagram illustrating a state of a wafer W before starting a process. A recessed pattern 130 is formed in a surface of the wafer W. The recessed pattern 130 may be a hole such as a through hole or a grove pattern such as a trench. Moreover, OH groups are formed on the surface of the wafer W before a source gas is supplied.

FIG. 20 C is a diagram illustrating an example of a source gas supply process. In the source gas supply process, an organic aminosilane gas, which is a source gas, is supplied from the first process gas nozzle 31 in the first process area P1, and is adsorbed on the surface of the recessed pattern 130 formed in the surface of the wafer W. Here, FIG. 20B illustrates an example of using C₆H₁₇NSi is used as the organic aminosilane gas.

FIG. 20D is a diagram illustrating a state of the recessed pattern 130 of the surface of the wafer W after the source gas supply process ends by using a chemical formula. As illustrated in FIG. 20D, O elements of the organic aminosilane gas adsorb on the surface of the wafer W including the recessed pattern 130.

FIG. 20E is a diagram illustrating a state of the recessed pattern 130 of the surface of the wafer W after the source gas supply process ends by using a film 140. After the source gas supply process ends, an adsorbed layer of the source gas is formed on the surface of the recessed pattern 130.

FIG. 20F is a diagram illustrating an example of an oxidation process and a modification process. In the oxidation process, an oxidation gas is converted to plasma and supplied to the surface of the wafer W including the recessed pattern 130 on which the aminosilane gas is absorbed, thereby performing a plasma process on the surface of the wafer W. Here, as illustrated in FIG. 20F, ozone gas is used as the oxidation gas, for example. By the oxidation process, H groups of the tips illustrated in FIG. 20D are released from the adsorbed source gas, and the number of H groups decreases. Then, in the modification process, the number of H groups further decreases. When the OH groups are present at the tips, the organic aminosilane gas that is the source gas is likely to adsorb thereon, and serves as an adsorption site. In contrast, the O groups are present at the tips, the organic aminosilane gas is unlikely to adsorb thereon.

FIG. 20G is a diagram illustrating a state of the surface of the wafer W including the recessed pattern 130 after the oxidation process and the modification process. As illustrated in FIG. 20G, the oxidation occurs around the bottom surface to such a degree that the tips become the OH group, and the complete oxidation occurs around the top end and the surface of the wafer W to such a degree that the tips become the O groups. By creating such a state, the source gas adsorbs only on around the bottom surface, and does not adsorb on around the top end and the surface of the wafer W, which makes it possible to deposit a film from the bottom surface of the recessed pattern 130, and to implement a so-called bottom-up film deposition.

In this process, because intense plasma creates the O groups while moderate plasma creates the OH groups, the OH groups are likely to increase on the peripheral side of the turntable 2 where the plasma is likely to weaken, and the film thickness on the peripheral side is likely to become thicker than that on the central side. Hence, by generating the plasma in the peripheral area of the turntable 2 and the concave portion 24 in the third process area P3, the state illustrated in FIG. 20G can be implemented.

FIG. 20H is a diagram illustrating a state of the surface of the wafer W including the recessed pattern 130 after the oxidation process and the modification process by using a film 141. In this state, a conformal film 141 along the recessed pattern 130 is formed.

FIG. 20I is a diagram illustrating an example of a second source gas supply process. In the second source gas supply process, the organic aminosilane gas is supplied from the first process gas nozzle 31 to the wafer W in the first process area P1 again.

FIG. 20J is a diagram illustrating a state of the surface of the wafer W including the recessed pattern 130 after the second source gas supply process by using a chemical formula. As illustrated in FIG. 20J, a Si layer increases around the bottom of the recessed pattern 130 by the adsorption of the aminosilane gas. In contrast, the Si layer does not increase around the top end of the recessed pattern 130 and the surface of the wafer W.

FIG. 20K is a diagram illustrating a state of the surface of the wafer W including the recessed pattern 130 after the second source gas supply process by using films 140 and 141. As illustrated in FIG. 20K, the film thickness increases around the bottom of the recessed pattern 130, and the film thickness decreases around the top end of the recessed pattern 130 and the surface of the wafer W. Thus, the film deposition is performed to form the film into a V-letter shape, and the film deposition with high bottom-up properties, thereby performing the film deposition that prevents a void from being generated.

In the modification process in FIG. 20F discussed above, by performing the additional plasma process only on the periphery where the degrees of reaction and plasma process are weak, the film deposition with the high bottom-up properties as illustrated in FIGS. 20J and 20K can be performed, and the generation of void can be prevented, which makes it possible to perform the film deposition process in response to the recessed pattern 130 with a high aspect ratio.

In contrast, in the film deposition of a SiN film and the like, when the plasma process is insufficient, nitriding becomes insufficient, which is likely to decrease film quality and unlikely to acquire the sufficient film thickness. Even in such a case, by performing the additional and complementary plasma process on the area where the plasma process is likely to become insufficient, for example, on the periphery of the turntable 2.

Thus, according to the plasma processing apparatus and the film deposition method of the first embodiment of the present invention, the plasma process with high uniformity can be performed on the wafer W by providing the second plasma generator 180 that can selectively perform the plasma process only on a desired area in addition to the first plasma generator 80 that can perform the whole surface of the wafer W.

### Second Embodiment

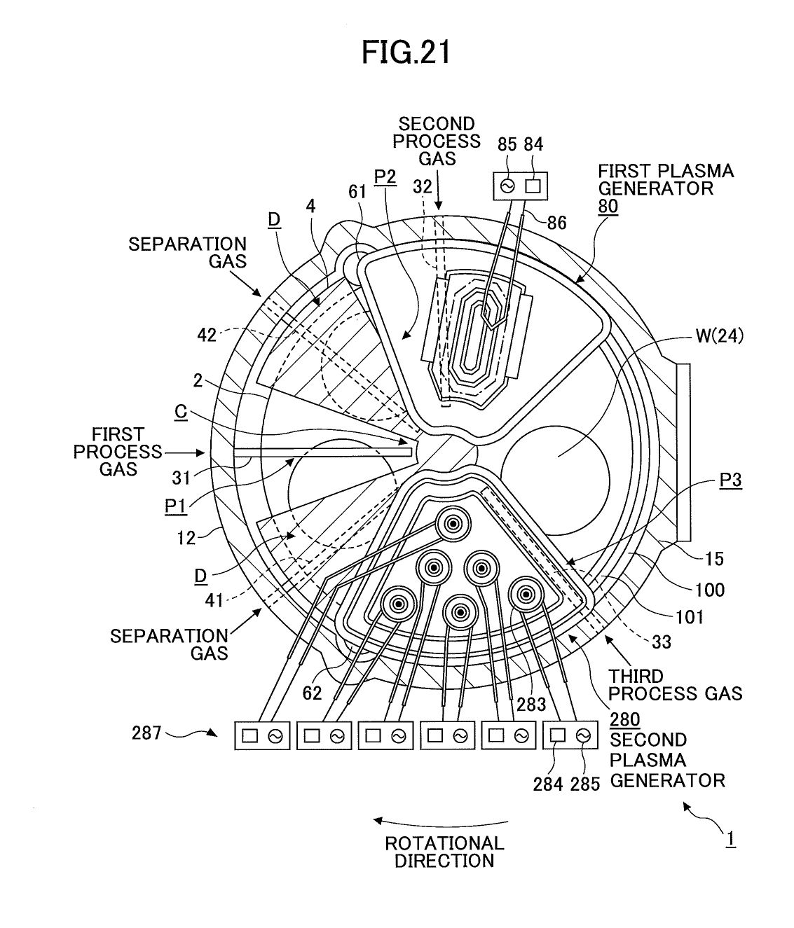

FIG. 21 is a plan view illustrating an example of a configuration of a plasma processing apparatus according to a second embodiment. The plasma processing apparatus according to the second embodiment is similar to the plasma processing apparatus according to the first embodiment in that the plasma processing apparatus according to the second embodiment includes the first plasma generator 80 and the second plasma generator 280, but is different from the plasma processing apparatus according to the first embodiment in that the second plasma generator 280 includes a plurality of antennas 283, matching boxes 284 and radio frequency power sources 285 provided independently of each other. Because the other components are the same as those of the plasma processing apparatus according to the first embodiment, the description is omitted.

As illustrated in FIG. 21, the plasma processing apparatus according to the second embodiment includes six antennas 283 arranged to cover almost the entire area of the third process area in the radial direction of the turntable 2. Each of the independent matching boxes 284 and radio frequency power source 285 is connected to each of the six antennas 283. Due to such a configuration, each of the six antennas 283 can be separately controlled, and plasma can be generated by supplying radio frequency power only to the antenna 183 provided in a desired area. For example, in this manner, by providing a plurality of small plasma generators 287, each of which is small and covers a small area, the plasma generator 280 that can locally control the generation of plasma may be configured.

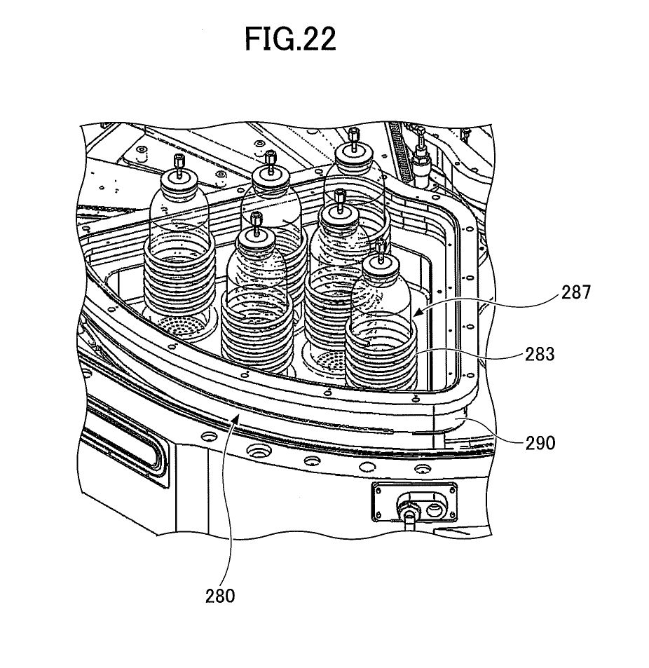

FIG. 22 is a perspective view of the second plasma generator 280 of the plasma processing apparatus according to the second embodiment. As illustrated in FIG. 22, six of the small plasma generators 287 that are constituted of six ICP (Inductively Coupled Plasma) for control are arranged, and forms the plasma generator 287 as a whole. Because each of these small plasma generators independently includes the matching box 284 and the radio frequency power source 285, plasma intensity can be independently controlled. Moreover, each of the antennas 283 of the small plasma generator 287 is arranged in a housing 290, similarly to the first embodiment.

Accordingly, the plasma process can be independently performed on an area where the degree of plasma process is insufficient in the second process area P2, which makes it possible to improve the uniformity of plasma process across the surface of the wafer W.

Thus, the second plasma generator 280 may be configured to perform the plasma process only in a desired area by providing the plurality of independent small plasma generator 287. The local plasma generation unit differs from that of the first embodiment, but can have a similar effect to the first embodiment in the film deposition method.

In the first and second embodiments, the plasma processing apparatus and the film deposition method using the turntable 2 are described, but the embodiments of the present invention can be applied to a plasma processing apparatus and a film deposition method using an unrotatable susceptor as a substrate receiving area by providing the plasma generator 80 whose plasma conditions are fixed and the plasma generator 180 or 280 that can change the process area, and the amount of plasma process can be adjusted.

Moreover, even when a single wafer processing type turntable that receives only a single wafer W is used, the embodiments of the present invention can be applied because the uniformity across the surface of the wafer W can be improved by the local plasma process. In addition, even in the single wafer processing type, because the plasma process on the periphery of the turntable 2 is likely to be insufficient due to the difference of angular rate similarly to the embodiments of the present invention, the embodiments of the present invention can be preferably applied to the single wafer processing type plasma processing apparatus.

According to the embodiments of the present invention, there is provided a plasma processing apparatus and a film deposition method that can compensate a disproportion of a plasma process.

All examples recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority or inferiority of the invention. Although the embodiments of the present invention have been described in detail, it should be understood that various changes, substitutions, and alterations could be made hereto without departing from the spirit and scope of the invention.

What is claimed is:

1. A plasma processing apparatus comprising:
a process chamber;
a susceptor provided in the process chamber and having a substrate receiving area formed in a top surface thereof;
a first plasma generator configured to perform a first plasma process on a first predetermined area in the substrate receiving area;
a first radio frequency power source connected to the first plasma generator and configured to supply first radio frequency power to the first plasma generator;
a second plasma generator configured to perform a second plasma process on a second predetermined area in the substrate receiving area and to be able to change the second predetermined area; and
a second radio frequency power source connected to the second plasma generator and configured to supply second radio frequency power to the second plasma generator.

2. The plasma processing apparatus as claimed in claim 1, wherein the first predetermined area to be subject to the first plasma process includes the whole area of the substrate.

3. The plasma processing apparatus as claimed in claim 1,
wherein the second plasma generator includes a main antenna connected to the second radio frequency power source and an auxiliary antenna that is not connected to the second radio frequency power source and in an electrically floating state, and
the main antenna and the auxiliary antenna are configured to cause an inducted current to flow though the auxiliary antenna by electromagnetic induction between the main antenna and the auxiliary antenna.

4. The plasma processing apparatus as claimed in claim 3, wherein the main antenna and the auxiliary antenna are arranged to perform the second plasma process on different areas in the substrate receiving area from each other.

5. The plasma processing apparatus as claimed in claim 4, wherein the main antenna and the auxiliary antenna are arranged to perform the second process on the whole area of the substrate receiving area in combination with each other.

6. The plasma processing apparatus as claimed in claim 3,
wherein a capacitance variable mechanism capable of changing a capacitance thereof is connected to the auxiliary antenna, and
the second predetermined area to be subject to the second plasma process is changed by adjusting an impedance of a loop formed of the second auxiliary antenna and the capacitance variable mechanism.

7. The plasma processing apparatus as claimed in claim 1,
wherein the second plasma generator includes a plurality of third plasma generators each of which can perform the second plasma process on a different area in the substrate receiving area, and
the second radio frequency power source includes a plurality of third radio frequency power sources capable of separately supplying third radio frequency power to each of the plurality of third radio frequency power sources.

8. The plasma processing apparatus as claimed in claim 1, wherein the susceptor is a rotatable turntable.

9. The plasma processing apparatus as claimed in claim 8,
wherein the turntable includes a plurality of substrate receiving areas provided along a circumferential direction thereof,
wherein the first plasma generator and the second plasma generator are provided apart from each other in the circumferential direction,
wherein the first plasma generator covers the first predetermined area in each of the plurality of substrate receiving areas in a radial direction of the turntable, and
wherein the second plasma generator covers the second predetermined area in each of the plurality of substrate receiving areas in the radial direction of the turntable.

10. The plasma processing apparatus as claimed in claim 9,
wherein the second plasma generator is provided downstream of the first plasma generator in the rotational direction of the turntable.

11. The plasma processing apparatus as claimed in claim 10, further comprising:
a source gas supply unit to supply a source gas to the substrate receiving areas and provided upstream of the first plasma generator in the rotational direction of the turntable;
a reaction gas supply unit to supply a reaction gas capable of producing a reaction product by reacting with the source gas to the substrate receiving areas and provided below the first plasma generator; and
a modification gas supply unit to supply a modification gas to modify the reaction product and provided below the second plasma generator,
wherein a film deposition process and a modification process of the film can be performed by rotating the turntable so as to cause the plurality of substrates to pass areas under the source gas supply unit, the reaction supply gas unit and the modification gas supply unit in this order.

12. The plasma processing apparatus as claimed in claim 11, further comprising:
a first purge gas supply unit provided between the source gas supply unit and the reaction gas supply unit; and
a second purge gas supply unit provided between the modification gas supply unit and the source gas supply unit.

13. A film deposition method comprising steps of:
supplying a source gas to a surface of a substrate;
supplying a reaction gas capable of producing a reaction product by reacting with the source gas to the surface of the substrate while converting the reaction gas to plasma, thereby depositing the reaction product on the surface of the substrate; and
correcting a disproportion of a degree of reaction of the source gas on the surface of the substrate with the reaction gas by supplying the reaction gas while converting the reaction gas to plasma to an area where the degree of reaction of the source gas on the surface of the substrate with the reaction gas is smaller than the other area.

14. The film deposition method as claimed in claim 13, further comprising:
placing the substrate on a surface of a turntable,
wherein the steps of supplying the source gas, supplying the reaction gas and correcting the disproportion of the degree of reaction are performed by rotating the turntable, and
wherein the area where the degree of reaction of the source gas with the reaction gas is less than the other area is a peripheral area of the turntable.

15. The film deposition method as claimed in claim 14,
wherein a plurality of substrates are placed on the turntable along a circumferential direction of the turntable, and
the steps of supplying the source gas, supplying the reaction gas and correcting the disproportion of the degree of reaction of the source gas on the plurality of substrates with the reaction gas are periodically and repeatedly performed by rotating the turntable so as to cause the plurality of substrates to pass through a source gas supply area, a reaction gas supply area and a reaction degree adjustment area that are arranged apart from each other in a rotational direction of the turntable sequentially and periodically.

16. The film deposition method as claimed in claim 15, further comprising steps of:
supplying a purge gas to the substrates between the steps of supplying the source gas and supplying the reaction gas, and between the steps of correcting the degree of reaction of the source gas on the surface of the substrates with the reaction gas, performed by providing purge gas supply areas between the source gas supply and the reaction gas supply area, and between the reaction degree adjustment area and the source gas supply area, respectively.

17. The film deposition method as claimed in claim 16,
wherein a recessed pattern is formed in a surface of each of the substrates,
wherein the source gas is an organic aminosilane gas,
wherein the reaction gas is an oxidation gas,
wherein the step of supplying the reaction gas includes a step of supplying the oxidation gas to the surface of each of the substrates in order to oxidize a top end of the recessed pattern and the surface of each of the substrates so as not to leave hydrogen contained in the organic aminosilane gas while leaving hydrogen contained in the organic aminosilane gas on and around a bottom of the recessed pattern so as to leave an OH group as an adsorption site of the source gas, and
wherein the step of correcting the degree of reaction of the source gas on the surface of the substrate includes a step of supplying the oxidation gas to a peripheral area of the turntable so as to improve a degree of oxidation in the peripheral area.
